(19) United States
(12) Patent Application Publication
(10) Pub. No.: US 2015/0194608 A1
(43) Pub. Date: Jul. 9, 2015

(54) BUILDING BLOCK FOR LOW BANDGAP CONJUGATED POLYMERS

(71) Applicants: THE REGENTS OF THE UNIVERSITY OF CALIFORNIA, Oakland, CA (US); MITSUBISHI CHEMICAL CORPORATION, Tokyo (JP)

(72) Inventors: Chien-Yang Chiu, Goleta, CA (US); Hengbin Wang, Santa Barbara, CA (US); Hung Phan, Goleta, CA (US); Fulvio G. Brunetti, Singapore (SG); Craig J. Hawker, Santa Barbara, CA (US); Fred Wudl, Montecito, CA (US)

(73) Assignees: MITSUBISHI CHEMICAL CORPORATION, Tokyo (JP); THE REGENTS OF THE UNIVERSITY OF CALIFORNIA, Oakland, CA (US)

(21) Appl. No.: 14/589,798

(22) Filed: Jan. 5, 2015

Related U.S. Application Data
(60) Provisional application No. 61/923,363, filed on Jan. 3, 2014.

(51) Int. Cl. H01L 51/00; C08L 81/02; C08L 77/00; C08G 75/06; C08G 69/42

(52) U.S. Cl. CPC H01L 51/0036; C08G 75/06; C08G 69/42; C08L 77/00; C08L 81/02; H01L 51/42

(57) ABSTRACT

A twisted but conjugated building block for low bandgap conjugated polymers. An organic device comprising a (E)-8,8′-biindeno[2,1-b]thiophenylidene (tBTP) based polymer.

### CROSS REFERENCE TO RELATED APPLICATIONS

This application claims the benefit under 35 U.S.C. Section 119(e) of U.S. Provisional Patent Application Ser. No. 61/923,363 filed on Jan. 3, 2014, by Chien-Yang Chiu, Hengbin Wang, Fulvio G. Brunetti, Craig J. Hawker, and Fred Wudl, entitled “BUILDING BLOCK FOR LOW BANDGAP CONJUGATED POLYMERS,” attorney's docket number 30794.533-US-P1 (2014-311-1), which application is incorporated by reference herein.

### BACKGROUND OF THE INVENTION

1. Field of the Invention

This invention relates to a building block for low bandgap conjugated polymers.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

A new generation of electronic devices, including organic field-effect transistors (OFETs) or Organic Thin Film Transistors (OTFTs), organic photovoltaic cells (OPVs), and organic light-emitting diodes (OLEDs), have been fabricated using organic semiconductors as their active components. Conjugated polymers are useful in these devices as they combine the electrical properties of semiconductors with the mechanical properties of plastics. Moreover, these materials can be processed inexpensively by techniques such as spin-coating and ink jet printing. Conjugated polymers can be designed to form active layers in these types of electronic devices, and provide promising materials for optimizing the performance of existing devices as well as the development of new devices.

Field-effect transistors (FETs) fabricated from conjugated polymers are candidates for use in flexible, transparent, and low-cost electronic applications, such as electronic paper or OLED displays [1]. In addition to the advantage of cost-effective production from solution processing, polymer based FETs also have the potential for excellent charge transport characteristics. During the past decade, improvements in conjugated polymer design and device fabrication have resulted in the achievement of field-effect mobilities close to that of amorphous silicon (0.1˜1 cm²V/s).

OFETs are of particular interest because of the continuing improvements in the charge carrier mobility, together with unique properties such as flexibility, transparency, and low cost, that are promising for use in “plastic electronics”. Significant progress has been made in solution-processed OFETs based on small molecules and polymer semiconductors (mobility ≈10 cm²/Vs), which bring such devices closer to industrial application [2-4]. The advantage(s) of OFETs for applications include, or are focused on achieving, low-cost and high throughput printing processes for mass production [5-7]. Polymer semiconductors offer better potential for excellent charge transport as well as better film forming and mechanical properties, compared with their small molecular counterpart [8].

Converting photo energy from sunlight to electricity that can be used in daily life has been successfully demonstrated using photovoltaics (PV) [9-10]. In the last decades, great attentions have been focused on organic solar cells (OSCs) for the need of cost effective manufacturing on large area and flexible substrates [11,12]. Thus far, the most efficient OSCs use a bulk-heterojunction (BHJ) architecture in a tandem cell configuration, with a world record power conversion efficiency (PCE) 12% being reported [13-18]. In addition, over the last decades, various building blocks comprising conjugated polymers for OSC applications have been synthesized; however, not many examples exist for the preparation of low bandgap (E_{g}<1.5 eV) conjugated polymers that can be used as the active materials in either single junction or tandem solar cells [19-22]. Therefore, other than shuffling currently existing monomers to prepare different polymer structures, a new category of monomer structure is desired to further explore in the field of polymer solar cells.

The Wudl group reported a series of electron accepting materials based on the structure of 9,9′-bifluorenylidene (99′BF) [23,24]. 99′BF types of materials possess very different energy levels from those of fullerene derivatives. In addition, 99′BF materials have wide versatility in terms of derivatization and functionalization since, in theory, there are twelve sites for functionalization by substitutions. From the Wudl group's studies, it was found that the 99′BF type of materials tend to accept electrons due to the steric strain relief and the fulfillment of the 14-π-electron rule, which makes them good candidates as the acceptor materials in organic solar cells. Although the lowest unoccupied molecular orbital (LUMO) energy offset between 99′BF derivatives and the donor material Poly(3-hexylthiophene-2,5-diyl) (P3HT) is merely within 0.12 electron volts (eV), they were still able to prepare a somewhat efficient solar cell with an open circuit voltage (V_{oc}) up to 1.20 V. In addition to their unique electrochemical properties, 99′BF materials show broad absorption in the visible region. These reports triggered our interest to further explore new materials and apply this type of material in a polymer structure which not only has potential as either a p-type or n-type polymer, but also as a low bandgap polymer for organic electronics.

### SUMMARY OF THE INVENTION

New conjugated polymers are desired for promising organic electronics applications. Design and synthesis of novel monomers for a new class of conjugated polymers are described here. 8,8′-biindeno[2,1-b]thiophenylidene (BTP), a novel building block for conjugated polymers, has been synthesized and used in polymerization structures. BTP is a structurally twisted but highly conjugated aromatic compound. It is worth noting that one structural isomer of BTP (BTP-r) with sulfur atoms pointing outward also exhibits a promising building block for novel conjugated polymers. However, based on Density Functional Theory (DFT) calculations, it has a more twisted structure with a splay angle of 28.7°, larger than that of BTP (splay angle 25.6°), and therefore it is likely to impede charge transport along the backbone structure of resulting polymers.

BTP has proven the ability to be an n-type material in organic solar cells with either P3HT or benzoporphyrin (BP). Its 2-positions for thiophene moieties can be functionalized by bromination and stannylation, for polymerization reactions (such as Stille and Suzuki-Miyaura coupling reactions). Brominated and stannylated BTP has never been reported and but has been successfully prepared here. The synthetic strategy for BTP is modular and very flexible because a wide range of substituted 2-bromobenzoates are either commercially available or easily prepared. Copolymerization with other known monomers, such as bisthiophene (2T), diketopyrrolopyrrole (DPP), benzodithiophene (BDT), dithienylsilole (DTS), and Indacenodithiophene (IDT) has resulted in low bandgap conjugated polymers, with broad light absorption and high charge mobility, that are desired for organic FETs and solar cells. Further modification of BTP with fluorine atoms can affect the energy levels of the resulting copolymers, which also demonstrate low bandgap properties, with E_{g}<1.5 eV. BTP-based conjugated polymers have shown promising results in solar cell devices with photo conversion efficiency over 4%, and ambipolarity with electron and/or hole mobility up to 0.09 cm²/Vs in OFET devices. Thanks to the modular synthesis, BTP is capable of being functionalized at various positions on its structure to further fine tune its molecular structure, electronic property, Highest Occupied Molecular Orbital (HOMO), and LUMO energy, so that an optimized polymer structure can be prepared for high performance organic transistors and solar cells.

One or more embodiments of the present invention disclose a polymer material having the following structural formula (one of ordinary skill in the art understands the formula includes enantiomers of the sulfur containing compound):

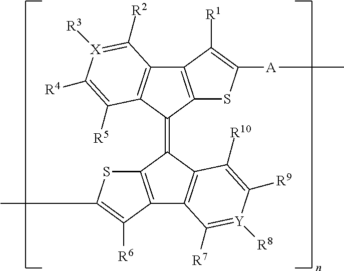

where n is an integer representing the number of repeats of the units between brackets in the polymer, X,Y can be independently equal to C, Nitrogen (N); and R¹-R¹⁰ can independently equal, but are not limited to, hydrogen, a halogen, an alkyl, a cyclic alkyl, a heterocyclic (e.g., heterocyclic alkyl), an alkyloxy, an alkylthio, an alkenyl, an alkynyl, an aryl, an aryloxy, an arylthio, a heteroaryl, a fluoroaryl, an amido, an amino, an acyl, a carboxyl, a cyano, an epoxy, a carboxylate, a nitro, a carbonyl, a sulfonyl, a sulfinyl, a cyano, a hydroxyl, a thiol, a silyl, a siloxy, a silyloxy, an azo, a boryl, a phosphoryl, a phosphinyl, or any combination thereof. R² and R¹⁰ can be equal to nothing when X or Y is nitrogen; and the polymer can be copolymerized with another monomer A (as illustrated, alternatively, the polymer may not include A). For example, monomer A can be chosen from a structure illustrated in FIG. 2B-2D, to form the copolymer.

For example, the polymer can have the following structure:

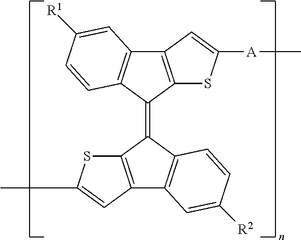

wherein:

n is an integer representing the number of repeats of the units between brackets in the polymer, R¹-R² are at least one member chosen from the hydrogen, the halogen, the alkyl, the cyclic alkyl, the heterocyclic, the alkyloxy, the alkylthio, the alkenyl, the alkynyl, the aryl, the aryloxy, the arylthio, the heteroaryl, the fluoroaryl, the amido, the amino, the acyl, the carboxyl, the cyano, the epoxy, the carboxylate, the nitro, the carbonyl, the sulfonyl, the sulfinyl, the cyano, the hydroxyl, the thiol, the silyl, the siloxy, the silyloxy, the azo, the boryl, the phosphoryl, and the phosphinyl.

Illustrative examples of copolymer unit include, but are not limited to, the structures illustrated in FIG. 2A (showing repeating units chosen from PtBTP2T, PtBTPDPP, PtBTPBDT, P4FBTPBDT, P4FBTPDTS, and PtBTPIDT). For example, the polymer can comprise a copolymer with the monomer chosen from diketopyrrolopyrrole (DPP), dithienylsilole (DTS), and benzodithiophene (BDT).

For example, the polymer can be fabricated using a process comprising Suzuki-Miyaura coupling methyl 2-bromobenzoate to form compound x; hydrolyzing the compound x to form compound y; performing a Friedel-Crafts reaction on compound y to afford a ketone; synthesizing BTP from the ketone by Lawesson's reagent; selecting one or more isomers of the BTP; and brominating and stannylating the isomers and performing polymerization reactions on the brominated and stannylated isomers to form the polymer.

For example, the polymer can comprise a plurality of (E)-8,8′-biindeno[2,1-b]thiophenylidene (BTP) units, each BTP unit having a nonplanar twisted structure having a splay angle (e.g., about 20-30 degrees) between proximal aromatic rings; the BTP units arranged in a monoclinic lattice with a sulfur-sulfur distance (e.g., about 3.4 Angstroms Å); and within the monoclinic lattice, the BTP units stacking themselves in a fully eclipsed fashion (e.g., with an intermolecular distance in the stack is about 3.5 Å).

For example, the splay angle can be such that the BTP is soluble in at least one solvent chosen from Tetrahydrofuran (THF), dichloromethane, ethyl acetate, and hexane.

For example, the polymer's backbone can be sufficiently rigid such that absorption profiles of the polymers in solution and film state are essentially identical.

For example, the polymer can be functionalized to have an optical bandgap in a range of 1.21-2.10 electron volts (eV). For example, the polymer can be functionalized or copolymerized to have a peak absorption at a wavelength between 600 nanometers (nm) and 900 nm.

For example, the polymer can be functionalized for solution casting on a device substrate, wherein the device is an organic light emitting device, organic light emitting diode, organic transistor, or organic photovoltaic device.

In one or more embodiments, the present invention discloses a photovoltaic device comprising the polymer, wherein the polymer comprises an active region, comprising an acceptor and a donor, the active region producing electrical power in response to incident electromagnetic radiation. For example, a photovoltaic cell structure on a substrate can include the active region comprising the acceptor and donor combined in a film on or above the substrate, the film having a structure, crystallinity, morphology, and thickness, donor/acceptor ratio, and amount of the polymer, wherein, measured at 1 sun (AM 1.5G), the photovoltaic cell structure has an open circuit voltage V_{oc} of at least 0.7 Volts (V) or in a range 0.54 V-0.79 V; a short circuit voltage J_{sc} of at least 8 milliamps per centimeter square (mA/cm²) or in a range of 0.81-10.2 mA/cm²; a fill factor ff of at least 0.65 or in a range of 0.29-0.65; and an efficiency η of at least 4.1% or in a range of 1-4.1%. In one or more embodiments, the polymer (e.g., in the photovoltaic device) can be functionalized to have an optical bandgap of at most 1.5 electron volts (eV).

One or more embodiments of the invention disclose a film, comprising one or more polymer chains comprising the polymer and having a carrier mobility, and means to adjust the carrier mobility of the polymer chains. For example, the film can comprise one or more polymer chains comprising an isomerically tuned linear polymer, the isomerically tuned linear polymer having an amount of compound comprising a trans isomer structure adjusted relative to an amount of cis-isomer of the compound in the film, such that the film's carrier mobility is isomerically tuned. For example, the film can comprise an amount of the compound B having the structural formula (and enantiomers thereof):

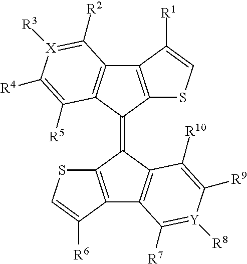

wherein the amount is adjusted relative to an amount of cis-isomer of B in the film, such that the film's carrier mobility is increased as compared to a carrier mobility of a control film where an amount of B is not adjusted relative to the amount of the cis-isomer.

One or more embodiments further disclose a film comprising a polymer (I), wherein the polymer (I) has the following structural formula:

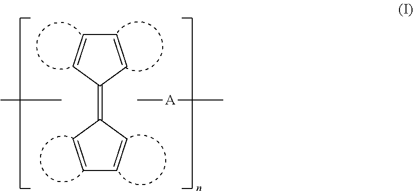

where

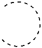

represents mono-cyclic or polycyclic aromatic rings fused to the fulvalene core, with or without substituents, wherein two of the rings comprise thiophene rings having Sulfur atoms positioned to form a trans isomer structure; an amount of the compound comprising the trans isomer structure is adjusted relative to an amount of cis-isomer of the compound in the film, such that the film's carrier mobility is isomerically tuned, A is a monomer, and n is an integer representing the number of repeats of the units between brackets in the polymer.

One or more embodiments of the invention further disclose an organic field effect transistor (FET) comprising the film, wherein the film comprises a conductive channel, the FET further comprising a substrate, wherein the film is on or above the substrate; a source contact and a drain contact electrically contacting the film, for passing a current through the conductive channel between the source contact and the drain contact; and a gate for controlling the current's flow when a voltage bias is applied across a dielectric layer between the conductive channel and the gate. In this organic FET example, (1) the polymer comprises a donor and an acceptor, (2) A comprises the donor and B comprises acceptor, or A comprises the acceptor and B comprises the donor, (3) the film is processed from a composition comprising the polymer dissolved in a solvent, and (3) the substrate, the source contact, the drain contact, the gate, the dielectric layer, a donor/acceptor ratio in the film, the film's thickness, the composition, and the amount of isomer B are effective to achieve a electron and/or hole mobility of at least 0.09 centimeter squared per Volt second (cm²/Vs).

One or more embodiments further disclose an organic FET comprising a polymer, wherein the polymer comprises a donor and an acceptor, A comprises the donor and compound B comprises acceptor, or A comprises the acceptor and compound B comprises the donor, and the FET has an electron and/or hole mobility of at least 0.09 cm²/Vs.

One or more embodiments of the present invention further disclose an organic device comprising a mixture of polymer I and one or more fullerene derivatives, wherein polymer I has the following structural formula:

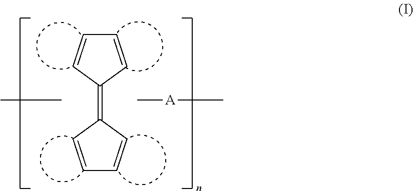

where

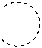

represents mono-cyclic or polycyclic aromatic rings fused to the fulvalene core, with or without substituents, the four rings can be the same or different. Examples of aromatic rings include, but are not limited to, acridine, anthracene, azaborinine, azaphosphinine, benzene, benzofuran, benzimidazole, benzothiazole, carbazole, β-carboline, cinnoline, isobenzofuran, benzothiophene, borole, furan, furazan, germole, imidazole, indazole, indole, indolizine, isoindole, isoquinoline, isothiazole, isoxazole, naphthalene, naphthyridine, oxadiazole, oxazole, phenanthridine, phenanthroline, phenazine, phosphole, phthalazine, pteridine, purine, pyrazine, pyrazole, pyridazine, pyridine, pyrimidine, pyrrole, quinoline, quinoxaline, quinazoline, silole, tetrazole, thiadiazole, thiazole, triazine, (1,2,3,)- and (1,2,4)-triazole, thiophene, or any combination thereof, and n is an integer representing the number of repeats of the units between brackets in the polymer.

Examples of substituents include, but are not limited to, hydrogen, a halogen, an alkyl, a cyclic alkyl, a heterocyclic (e.g., heterocyclic alkyl), an alkyloxy, an alkylthio, an alkenyl, an alkynyl, an aryl, an aryloxy, an arylthio, a heteroaryl, a fluoroaryl, an amido, an amino, an acyl, a carboxyl, a cyano, an epoxy, a carboxylate, a nitro, a carbonyl, a sulfonyl, a sulfinyl, a cyano, a hydroxyl, a thiol, a silyl, a siloxy, a silyloxy, an azo, a boryl, a phosphoryl, a phosphinyl, or any combination thereof.

The polymer (I) can be copolymerized with monomer A as illustrated in the structural formula (however, monomer A can be omitted). Illustrative examples of copolymer unit include, but are not limited to, the structures illustrated in FIG. 2A. For example, monomer A can be chosen from a structure illustrated in FIG. 2B-2D, to form a copolymer with the polymer (I).

The following definitions are provided for terms used in the claims. The term “alkyl” refers to straight chain and branched alkyl groups having from 1 to 30 carbon atoms. The term “alkyloxy” refers to the group “alkyl-O—” which includes, by way of example, methoxy, ethoxy, n-propyloxy, i-propyloxy, n-butyloxy, t-butyloxy, n-pentyloxy, 2-ethylhex-1-yloxy, dodecyloxy, isopentyloxy, and the like. The term “alkenyl” refers to alkenyl group having from 2 to 30 carbon atoms having at least one site of alkenyl unsaturation. The term “alkynyl” refers to alkynyl group having 2 to 30 carbon atoms and having at least one site of alkynyl unsaturation.

The term “cyclic alkyl” refers to cyclic alkyl groups of from 3 to 30 carbon atoms having single or multiple condensed cyclic rings which condensed rings may or may not be aromatic provided that the point of attachment is not at an aromatic carbon atom.

The term “aryl” refers to an aromatic carbocyclic group of from 6 to 30 carbon atoms having a single ring (e.g., phenyl) or multiple condensed rings (e.g., naphthyl or anthryl) which condensed rings may or may not be aromatic provided that the point of attachment is at an aromatic carbon atom. The term “aryloxy” refers to the group aryl-O— that includes, by way of example, phenoxy, naphthoxy, and the like.

The term “heterocyclic” refers to a saturated, unsaturated, or heteroaromatic group having a single ring or multiple condensed rings, from 1 to 30 carbon atoms and from 1 to 4 heteroatoms, selected from boron, nitrogen, phosphorus, oxygen, sulfur, selenium, —S(O)— and —S(O)₂— within the ring. Such heterocyclic groups can have a single ring (e.g., pyridyl or furyl) or multiple condensed rings (e.g., indolizinyl or benzothienyl) wherein the condensed rings may or may not be aromatic and/or contain a heteroatom provided that the point of attachment is through an atom of the heterocyclic group.

The term “heteroaryl” refers to an aromatic group of from 1 to 30 carbon atoms and 1 to 4 heteroatoms selected from the group consisting of boron, nitrogen, phosphorus, oxygen, nitrogen, sulfur, selenium, —S(O)—, and —S(O)₂— within the ring. The term “fluoroaryl” refers to an aromatic group of from 1 to 30 carbon atoms with at least one fluoro substitution.

The term “acyl” refers to the groups H—C(O)—, alkyl-C(O)—, alkenyl-C(O)—, alkynyl-C(O)—, cyclic alkyl-C(O)—, aryl-C(O)—, heteroaryl-C(O)— and heterocyclic-C(O)—, wherein alkyl, alkenyl, alkynyl, cyclic alkyl, aryl, heteroaryl, heterocyclic are as defined herein.

A “halogen” refers to a fluoro, a chloro, a bromo or an iodo. A “thiol” refers to the group —SH. A “carboxyl” refers to —COOH or COOR or salts thereof. An“amino” refers to the group —NH₂, NHR or NR¹R². An “alkylthio” refers to the group alkyl-S—. The term “arylthio” refers to the group aryl-S—. The term “amido” refers to the group —COONH₂, —COONHR, or —COONR¹R².

A “carboxylate” refers to a salt or ester of carboxylic acid, COO⁻, or COOR. A “nitro” refers to —NO₂. A “carbonyl” refers to —C(O)—. A “sulfonyl” refers to —S(O)₂—. A “sulfinyl’ refers to —S(O)—. A “cyano” refers to —CN. A hydroxyl refers to —OH. A “silyl” refers to —SiH₃, —SiH₂R, —SiHR¹R² or —SiR¹R²R³. A “siloxy” refers to —OSiH₃, —OSiH₂R, —OSiHR¹R² or —OSiR¹R²R³. An “azo” refers to —N═NR. A boryl refers to —BH₂, —BHR, —BR¹R². A “phosphoryl” refers to —P(O)H₂, —P(O)HR, or —P(O)R¹R². A “phosphinyl” refers to —PH₂, —PHR, or —PR¹R².

### BRIEF DESCRIPTION OF THE DRAWINGS

Referring now to the drawings in which like reference numbers represent corresponding parts throughout:

FIG. 1A, FIG. 1B, and FIG. 1C illustrate the chemical structure of 8,8′-biindeno[2,1-b]thiophenylidene in trans form (tBTP), and FIG. 1D, FIG. 1E, and FIG. 1F show the chemical structure of the trans-BTP-r form, wherein FIG. 1B and FIG. 1E are top views showing the positions of the Sulfur (S) (yellow), Carbon (C) (black), and Hydrogen (H) (gray) atoms, FIG. 1C and FIG. 1F are side views showing the splay angle, and the structures are based on Density Functional Theory (DFT) calculations (optimization b31yp/6-31+g(d)) that indicate that S atom position affects the molecule's splay angles.

FIG. 2A illustrates various BTP based copolymers synthesized according to one or more embodiments of the invention, and FIG. 2B, FIG. 2C, and FIG. 2D show illustrative examples of monomer unit A that can be used to form a copolymer with BTP, where C is Carbon, Si is Silicon, S is sulfur, Ge is Germanium, N is Nitrogen, H is Hydrogen, F is Fluorine, O is Oxygen, Se is Selenium, Pt is Platinum, and R is a group as defined in the specification, e.g., as for R¹-R¹⁰ or the definitions of terms given on pages 11-12 of this specification.

FIG. 3A, FIG. 3B, FIG. 3C, and FIG. 3D show cyclic voltammetry (CV) measurements of BTP derivatives, plotting current in micro amps (μA) vs. potential (volts) using acetonitrile with ferrocene (fc/fc⁺) as the internal standard, wherein two quasi-reversible reduction waves were observed in all the samples, demonstrating their electron accepting ability, and the scanning rate is 100 mV/s.

FIG. 4A shows scheme 1, synthesis of BTP and its derivatives (1a-1e), with i: sodium carbonate (Na₂CO₃), Palladium-tetrakis(triphenylphosphine) (Pd(PPh₃)₄); Tetrahydrofuran/water (THF/H₂O); ii: Sodium Hydroxide (NaOH), water/ethanol (H₂O/EtOH); iii: Oxalyl chloride, dichloromethane (CH₂Cl₂) and then Aluminum Chloride (AlCl₃); iv: Lawesson's reagent, toluene; FIG. 4B shows synthesis of brominated tBTP (tBTP-Br) and stannylated tBTP (tBTP-Sn), with v: N-Bromosuccinimide (NBS), Dichloromethane (DCM); vi: n-Butyllithium (ⁿBuLi), hexane and then SnMe₃Cl, THF; and FIG. 4C shows synthesis of a large BTP derivative BBTP, wherein 2a has the illustrated structure with R₁=R₂=H; 2b has the illustrated structure with R₁=methyl (CH₃) and R₂=H; 2c has the illustrated structure with R₁=Trifluoromethyl (CF₃) and R₂=H; 2d has the illustrated structure with R₁=Fluorine (F) and R₂=H; 2e has the illustrated structure with R₁=H and R₂=F, and 1a-1e, 2a-2e, 3a-3e, 4a-4e, 5a-5f are compound variations described throughout this disclosure, including the synthesis examples section of the disclosure.

FIG. 5A, FIG. 5B, and FIG. 5C show the crystal structure of tBTP (1a in FIG. 1) grown from solution, wherein FIG. 5A shows a top view of a BTP molecule in the crystal structure with a splay angle of about 20° between proximal benzene and thiophene rings, FIG. 5B shows BTP molecules in monoclinic arrangement with a close intermolecular sulfur-sulfur distance of about 3.4 Å, and FIG. 5C shows a side view of BTP columnar stacking in solid state with an intermolecular distance about 3.5 Å.

FIG. 6A shows Ultraviolet (UV)-visible (Vis) spectra of BTP derivatives, wherein the absorption of BTP peaks at a wavelength of 440 nm in the visible light region and reaches a wavelength over 600 nm, and FIG. 6B shows energy levels (HOMO, LUMO) of the BTP derivatives, wherein bandgap values are written within the shaded rectangles in FIG. 6B and the values in FIG. 6B are in electron volts.

FIG. 7 shows thermogravimetric analysis traces of BTP (1a), MeBTP (1b), and CF3BTP (1c), wherein the onset of decomposition temperature for each is at a temperature over 300 degrees Celsius (° C.).

FIG. 8A, FIG. 8B, FIG. 8C, and FIG. 8D show Scheme 2, synthesis of BTP-based conjugated polymers via Stille coupling, wherein i) is Pd₂dba₃, P(o-tol)₃, chlorobenzene and ii) is Pd₂dba₃, P(o-tol)₃, chlorobenzene, and microwave reaction, where Br is Bromine and Sn is Tin.

FIG. 9A and FIG. 9B show UV-Vis-Near Infrared (NIR) absorption of tBTP-based copolymers in solutions and as-cast films, wherein absorption of the PtBTPDPP film reaches a wavelength of 1200 nm.

FIG. 10 is a cross-sectional schematic of an organic photovoltaic device.

FIG. 11A shows current density-voltage curves for PtBTPBDT and PtBTPDPP polymer solar cell devices, with and without DIO additive, under AM 1.5G illumination, plotting current density J (mA/cm²) vs. potential (V), wherein the device structure is ITO/PEDOT:PSS/polymers:PC₆₁BM or PC₇₁BM (1:2 weight ratio)/Ca/Al, where ITO is Indium Tin Oxide, PEDOT:PSS is poly(3,4-ethylenedioxythiophene) poly(styrenesulfonate), Ca is Calcium, Al is Aluminum, and the polymer solution was prepared in chlorobenzene with various amount of DIO as additive, and FIG. 11B shows External Quantum Efficiency (EQE) curves of the devices prepared from mixture of chlorobenzene and various amount of DIO as additive.

FIG. 12A and FIG. 12B show top view Atomic Force Microscope (AFM) images of PtBTPBDT in solar cell devices, wherein FIG. 12A shows the AFM image when pure chlorobenzene was used as the processing solvent, and FIG. 12B shows the AFM image when 1.5% volume/volume (v/v) DIO was added into chlorobenzene as the processing solvent (and the morphology was significantly changed), wherein the legend shows surface roughness in nanometers (nm) and position in micrometers (μm).

FIG. 13 is a cross sectional schematic of an organic field effect transistor.

FIG. 14A shows transfer characteristics of OTFT devices with BTP based copolymer films at saturation regime (p-type transfer characteristics at drain voltage V_{d}=−80V), for copolymers P4FBTPBDT (squares), P4FBTPDTS (crosses), PtBTPDPP (circles), PtBTPIDT (dashes), and PtBTPBDT (triangles), and FIG. 14B shows the n-type transfer curves of an OTFT device based on copolymer PtBTPDPP, in both the linear (V_{d}=20V) and saturation (V_{d}=80V) regime, wherein all devices showed certain degree of ambipolarity, FIGS. 14A-B are measured for the device structure of FIG. 13, I_{d} (in amps, A) is the drain current entering to the polymer films from the source and flowing to the drain, V_{d} is the drain voltage (in volts) with respect to the source, the gate voltage or gate bias V_{G} is with respect to the source, and the notation 1E-10 is equivalent to 1×10⁻¹⁰.

FIG. 15 is a flowchart illustrating a method of fabricating a composition of matter and/or device.

FIG. 16 illustrates the structure of an isomerically tuned linear polymer.

FIG. 17 is a cross-sectional schematic of an organic light emitting diode.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

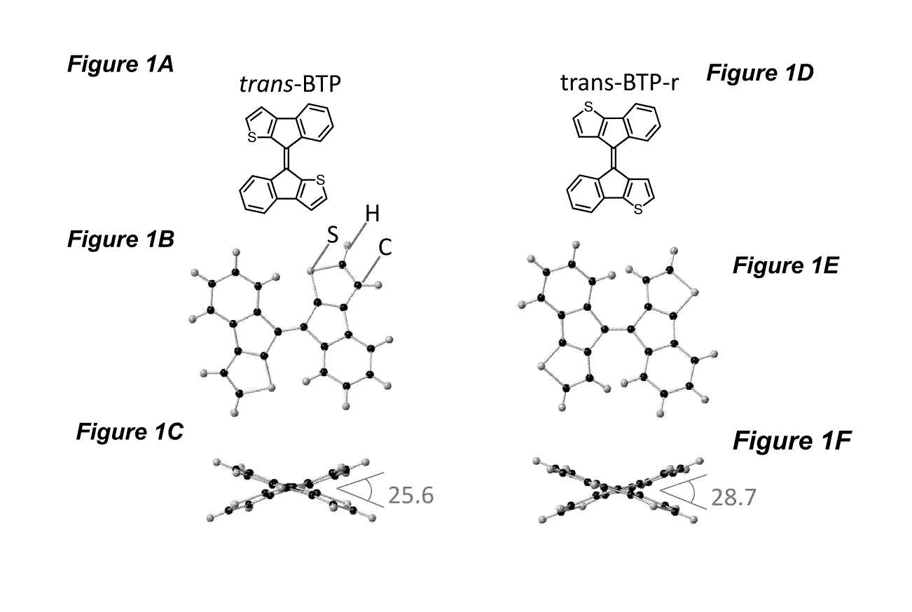

Here we report synthesis, properties, and polymerization of a new class of building blocks based on (E, or Z)-8,8′-biindeno[2,1-b]thiophenylidene (tBTP shown in FIG. 1), for application as low bandgap conjugated polymers. BHJ solar cell and field effect transistor results are presented.

FIGS. 1A, FIG. 1B, and FIG. 1C illustrate the chemical structure of 8,8′-biindeno[2,1-b]thiophenylidene in trans form (tBTP), and FIG. 1D, FIG. 1E, and FIG. 1F show the chemical structure of the trans-BTP-r form, showing the positions of the S, C, and H atoms.

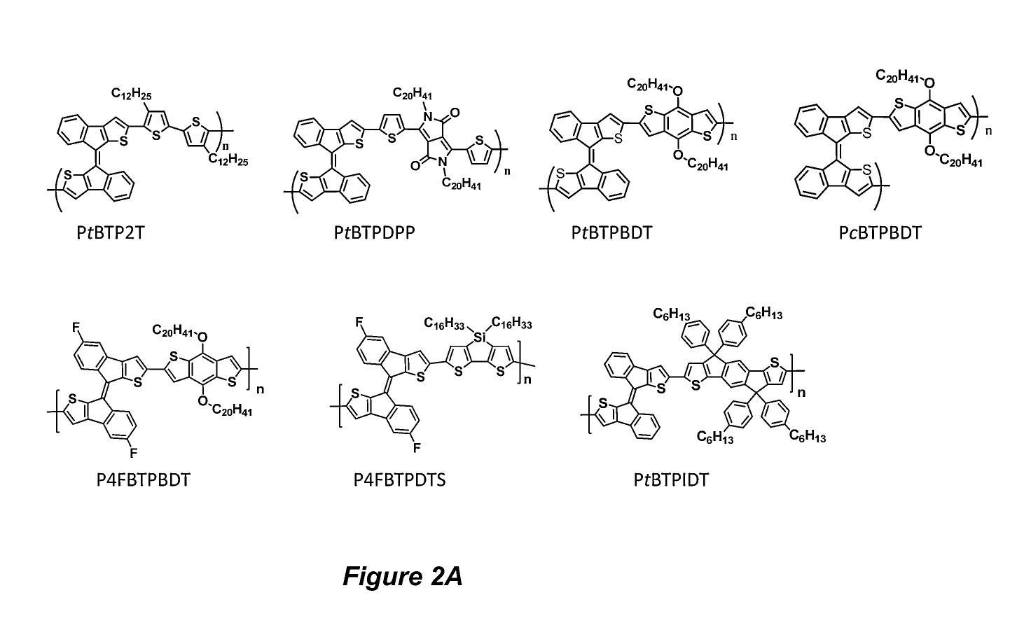

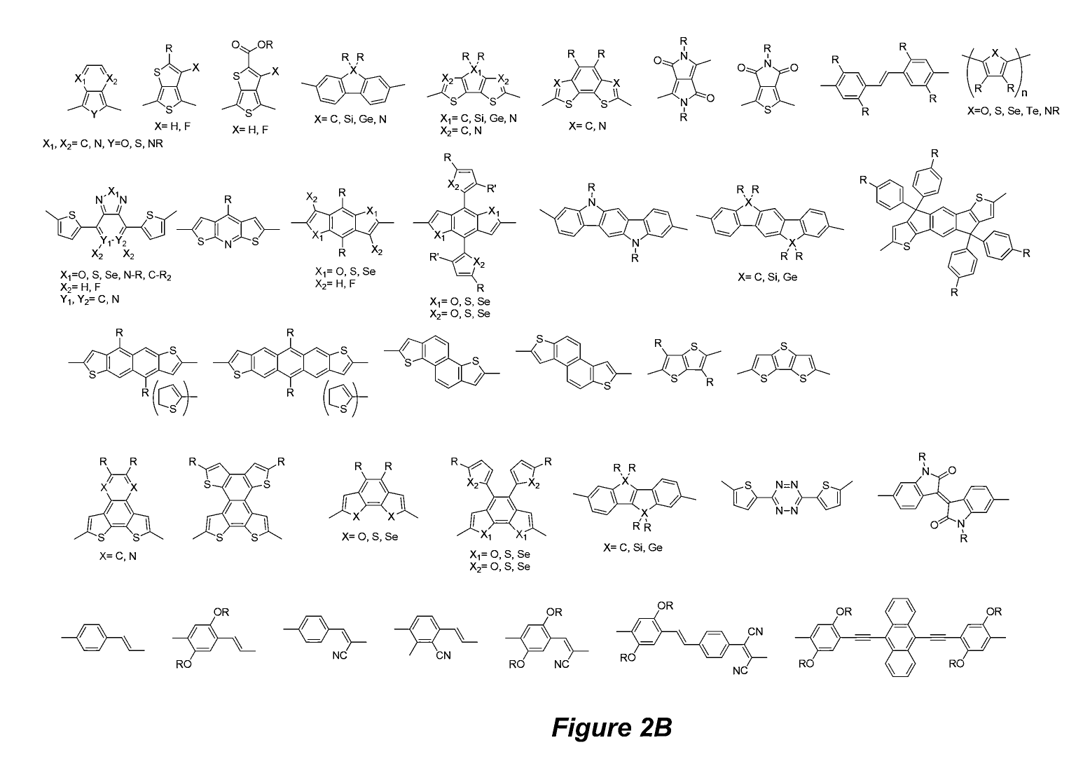

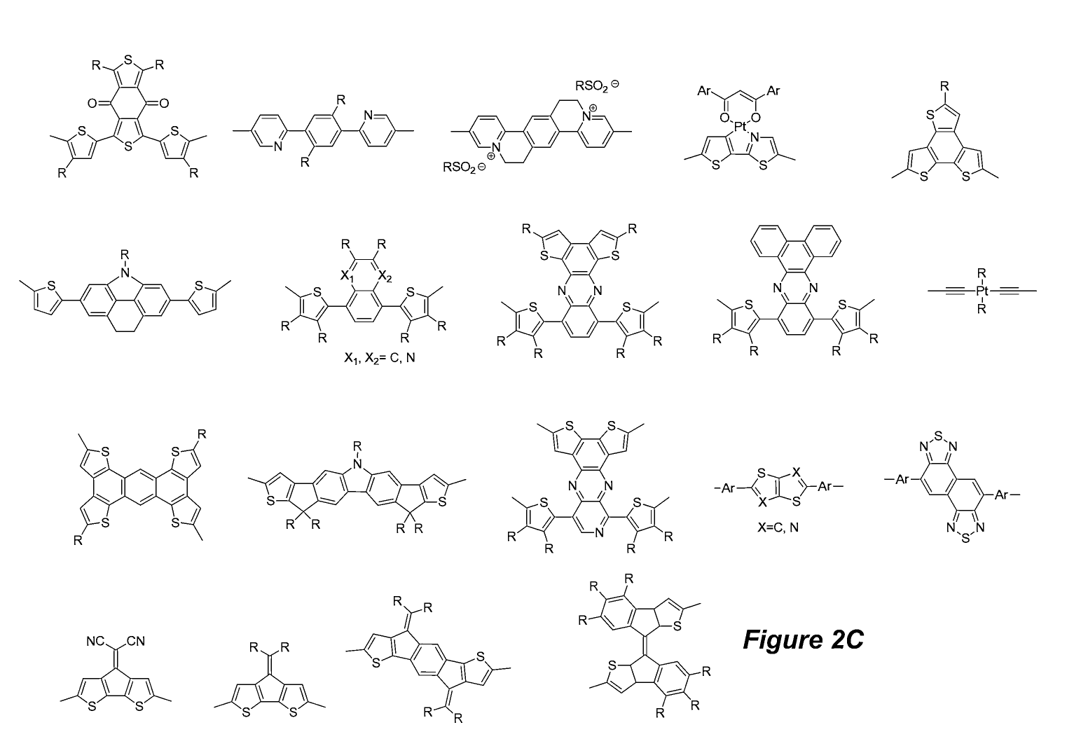

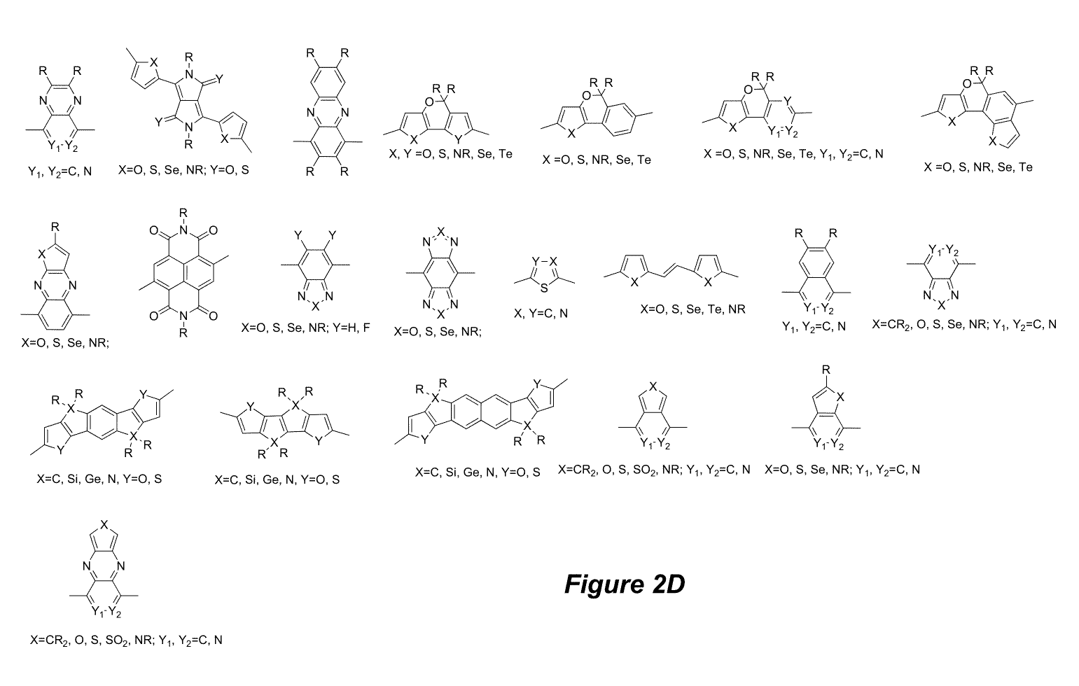

Examples of copolymer structures synthesized according to one or more embodiments of the invention are shown in FIG. 2A (other examples for the monomer A are shown in FIGS. 2B-2D).

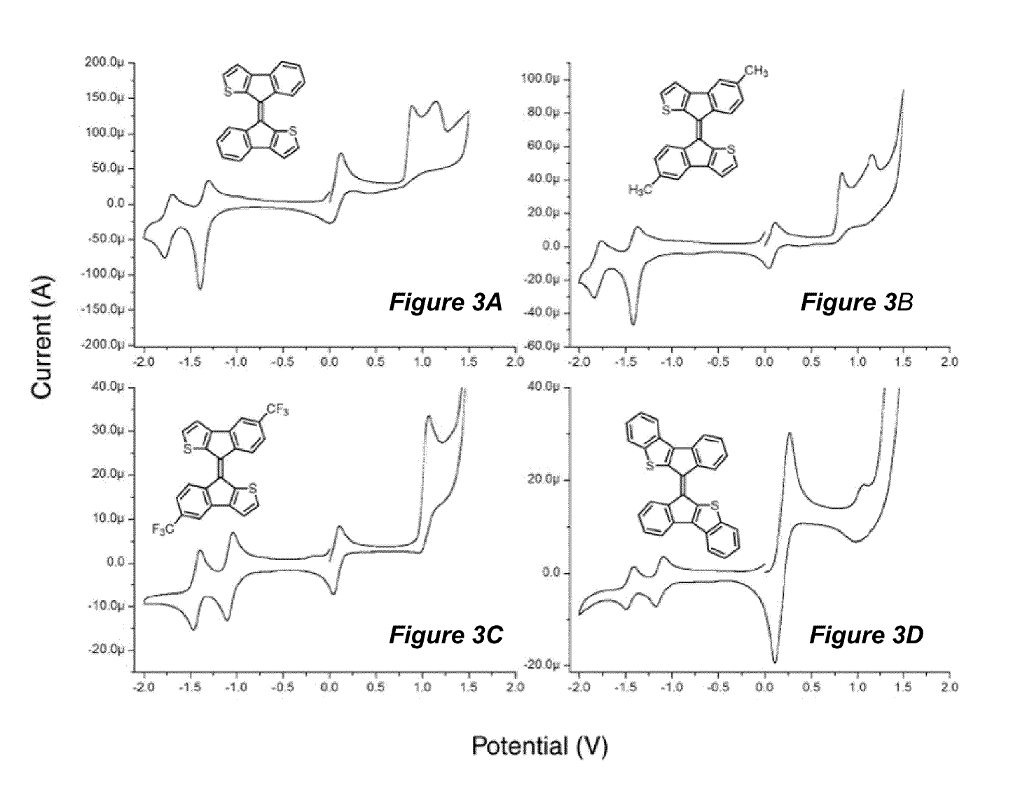

BTP is a cousin compound of 9,9′-bifluorenylidene (99′BF) that has proven to be a good electron acceptor. Similarly, BTP is able to accept two electrons to reach a lower energy state, presumably favored by releasing the steric strain from proximal aromatic rings and fulfilling a 14-π electron system [25]. The cyclic voltammetry (CV) measurement shows two reversible reduction waves (FIG. 3A). In general, the first reduction wave can be attributed to the formation of the radical anion, and the second to the corresponding dianion [26]. Using ferrocene as the internal standard, the HOMO and the LUMO were calculated to be 5.55 eV and 3.45 eV, respectively, with a bandgap E_{g}^{CV} (from CV)=2.10 eV. Note that this LUMO level is relatively higher than that of PC₆₁BM (E_{g}=3.8 eV); as an n-type material, BTP is potentially able to enhance V_{oc} in solar cell devices by increasing the energy gap between its LUMO and the HOMO of the donor material. The electron accepting ability and relatively high lying LUMO energy level potentially makes BTP a suitable n-type material in organic solar cells.

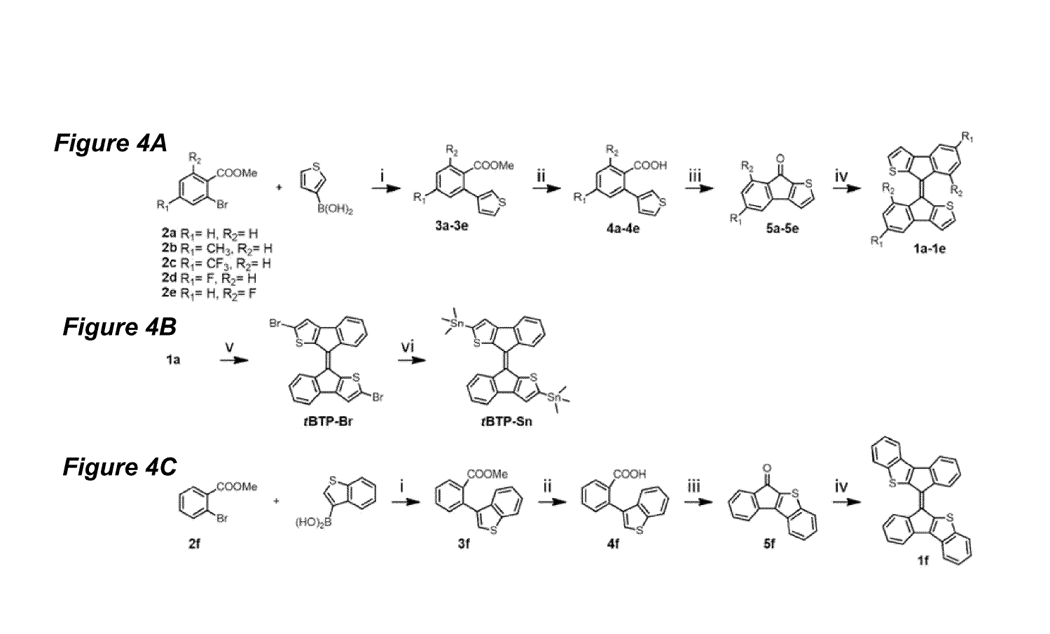

BTP and its derivatives have been successfully prepared with a simple synthesis and with a good yield (in FIG. 4A). BTP synthesis starts with Suzuki-Miyaura coupling of methyl 2-bromobenzoate 2a and 3-thiopheneboronic acid, followed by hydrolysis and then Friedel-Crafts reaction to afford the ketone 5a as a bright yellow solid. BTP synthesis is then furnished by Lawesson's reagent. This synthetic strategy is modular and very flexible, since a wide range of substituted 2-bromobenzoates are either commercially available or easily tailor-made. In the sense of stereochemistry, the Lawesson's reaction would give two isomers, one isomer with thiophenes on different sides, trans BTP (tBTP), and the other isomer with thiophenes on the same side, cis BTP (cBTP). Experimentally the ratio of trans to cis is about 2 to 1; presumably the more abundant trans isomer is the thermodynamic product since relatively severe repulsion between two benzene rings is avoided. The isomers show two different sets of Nuclear Magnetic Resonance (NMR) signals, indicating the protons are in essentially different electronic environments resulting from the dissimilarity in chemical structures. For the purpose of polymerization, pure trans and cis isomers, tBTP and cBTP, were isolated by recrystallization. The 2-positions on thiophene moieties can be further brominated and then stannylated consecutively for polymerization reactions as shown in FIG. 4B).

Variations in the synthesis and products are also illustrated in FIGS. 4A-4C, using and obtaining different compounds 1a-1e, 2a-2e, 3a-3e, 4a-4e, 5a-5f (see Synthesis Examples).

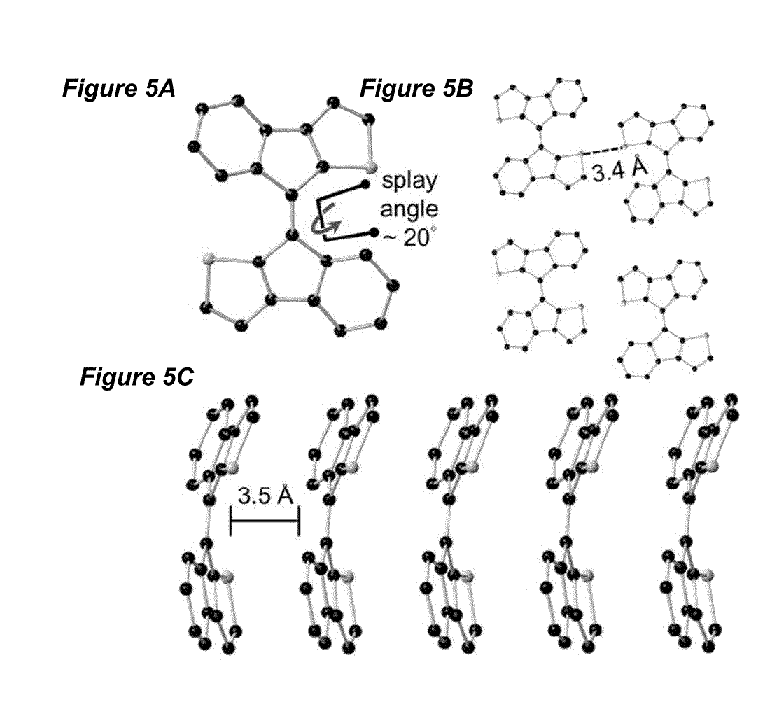

tBTP 1a was able to be isolated from its cis isomer by recrystallization from a mixing solvent of dichloromethane and hexane. Single crystal X-ray diffraction analysis shows 1a has a twisted structure, presumably resulting from the congestion between proximal aromatic rings; the splay angle between the thiophene and benzene rings is around 20 degrees (°) (FIG. 5A). The molecules arrange themselves into a monoclinic system with a short sulfur-sulfur distance of about 3.4 Å (FIG. 5B). Within the monoclinic lattice, these nonplanar molecules stack themselves into a fully eclipsed fashion with an intermolecular distance of about 3.5 Angstroms (Å) (FIG. 5C) This nonplanar structure renders BTP solubility in common solvents, such as THF, dichloromethane, ethyl acetate, acetonitrile, and hexane.

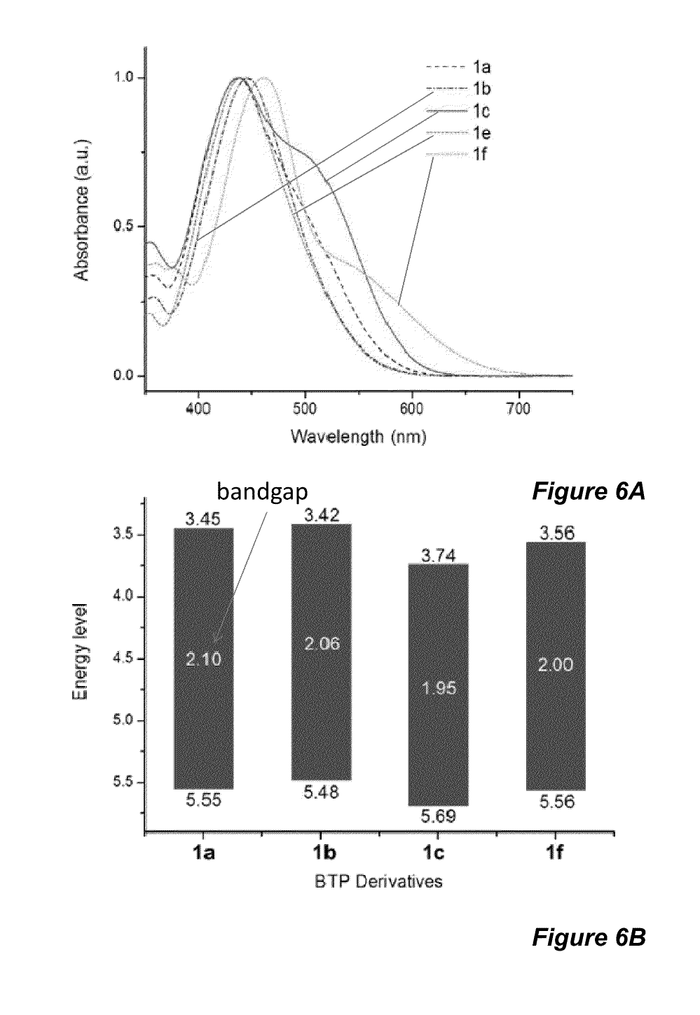

FIG. 6A shows the UV-Vis absorption spectra of BTP derivatives; here we used mixtures of isomers since trans and cis isomers give identical absorption spectra. As a small but highly conjugated molecule, BTP has a rather broad absorption; the maximum absorption is at a wavelength of about 450 nm and the absorption reaches a wavelength over 600 nm. This feature makes BTP a good building block for the preparation of low bandgap conjugated polymers. The optical bandgap estimated from the onset of absorption is about 2.10 eV, which matches well with the bandgap determined from the CV measurement. One or more optoelectronic properties of BTP can be readily tuned by functionalization of electron donating or accepting groups. Adding two methyl groups to BTP (1b FIG. 6A) shows a slight red-shift in the peak, with a narrower peak width being observed. On the other hand, adding two trifluoromethyl groups to BTP (1c, solid line in FIG. 6A) dramatically broadens the absorption, with the peak location remaining unchanged. Such a broad absorption could be beneficial for harvesting more solar energy. Further investigation using cyclic voltammetry (CV) reveals low bandgaps for both BTP derivatives (FIG. 6B). Methylated BTP 1b has a bandgap 2.06 eV; however trifluoromethyl substituents further lower the bandgap to 1.95 eV. Both derivatives are suitable for helping synthesize low bandgap conjugated copolymers. Further, looking into their HOMO and LUMO levels, electron donating methyl groups increase both the HOMO and the LUMO levels by about 0.03 eV. Adding two electron withdrawing trifluoromethyl groups to BTP, however, lowers both the HOMO and the LUMO levels by about 0.14 eV and 0.29 eV, respectively. This lower HOMO level can be used to tune the BTP-based copolymers to enhance solar cell performance by increasing V_{oc}.

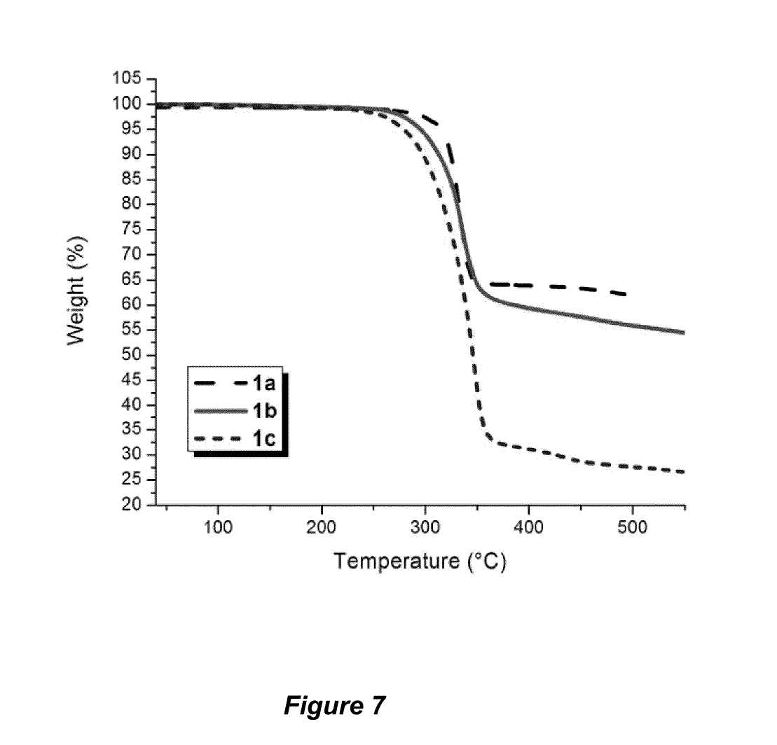

The thermal properties of BTP were measured by thermogravimetric analysis (TGA). TGA shows that BTP and its derivatives (1a-1c) have good thermal stability with decomposition temperature (T_{d}) over 300° C. (FIG. 7), which fulfills one of the basic requirements for sustainable organic devices.

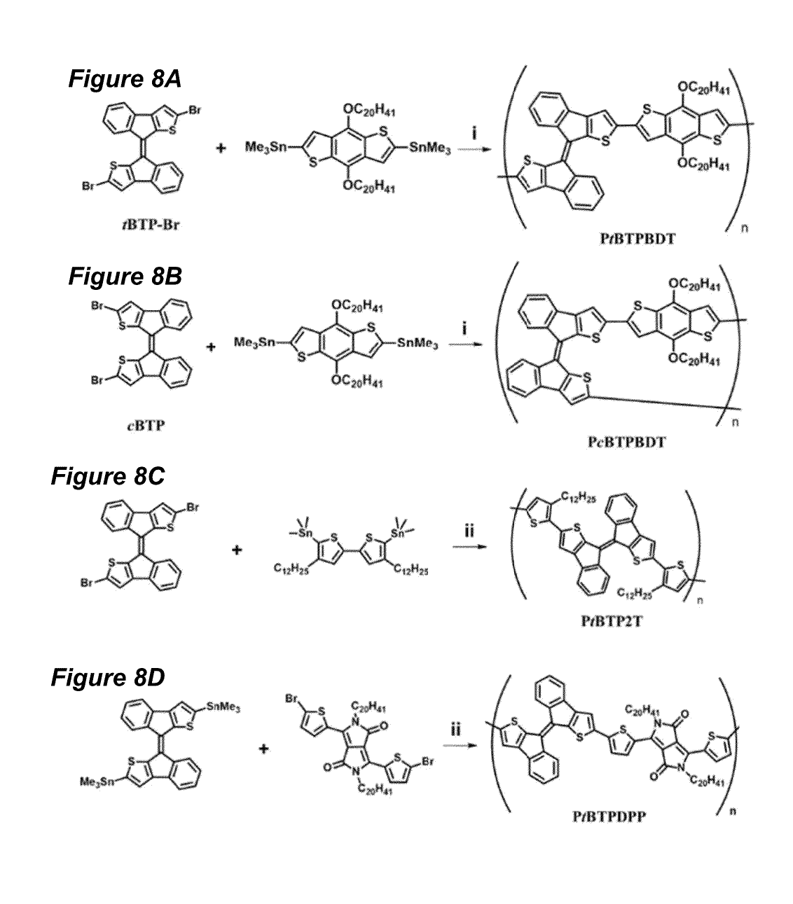

To demonstrate its ability to prepare low bandgap conjugated polymers, tBTP was copolymerized with several monomers including bisthiophene, diketopyrrolopyrrole (DPP) benzodithiophene (BDT), dithienylsilole (DTS) and Indacenodithiophene (IDT), respectively, via Stille coupling (Scheme 2 shown in FIG. 8). These polymerization reactions using either BTP-Br or BTP-Sn demonstrate BTP is versatile for different functionalization to accommodate different needs in polycondensation reactions. cBTP (cis:trans=9:1) was isolated and copolymerized with benzo-dithiophene (BDT) (to form PcBTPBDT), for comparison with PtBTPBDT. A di-fluorinated tBTP, 4FBTP (compound 1d) was copolymerized with benzodithiophene (BDT) and dithienylsilole (DTS) monomers to achieve copolymers with lower HOMO and stronger electron conducting capability. Examples of structures of the copolymers synthesized according to one or more embodiments of the invention are listed in FIGS. 2A-2D.

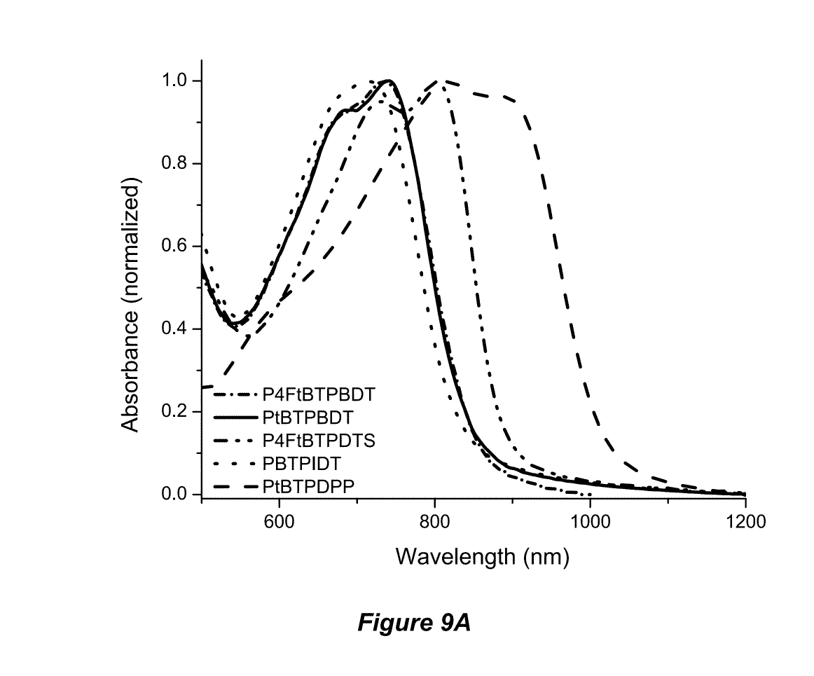

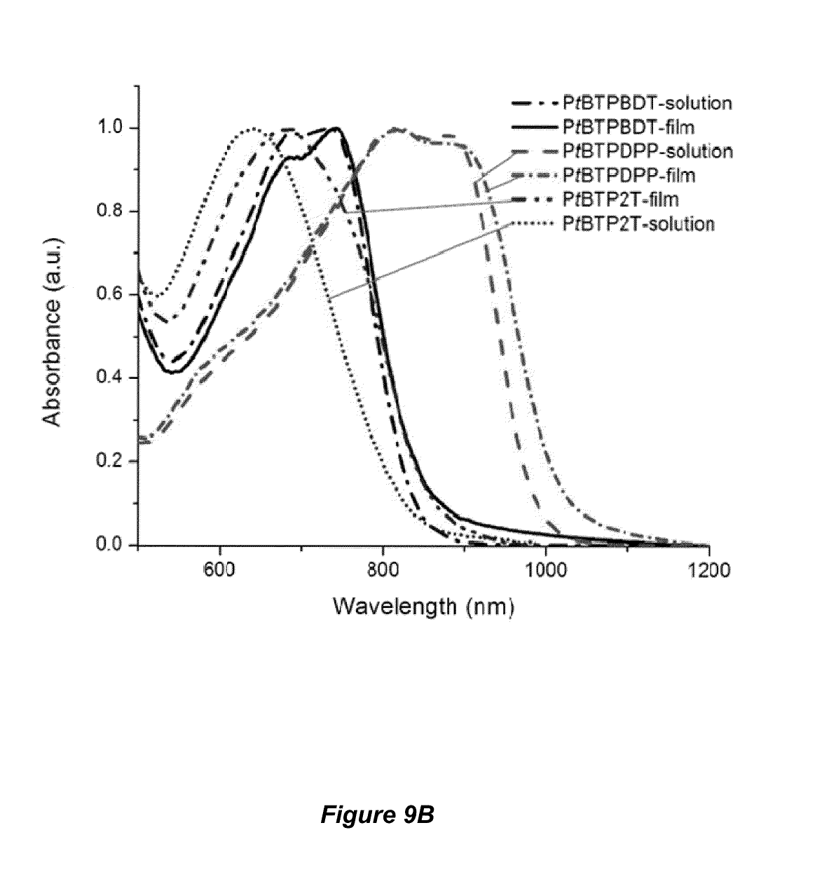

Optical properties of BTP-based copolymers were investigated by UV-Vis-NIR spectroscopy, in solution and spin-coated films, as shown in FIGS. 9A and 9B. No significant differences are observed in the absorption profiles of PtBTPDPP and PtBTPBDT, between the solution and film states, which indicates the conformations of both polymer backbones in the solution and solid state are essentially identical. The absence of bathochromic shifts from solutions to films can be attributed to the rigid polymer backbones of the subunits in both polymers and probable pre-aggregation in solutions. All copolymers show broad absorption covering the visible light region and significant absorption at wavelengths over 800 nm, with the PtBTPDPP polymer film reaching absorption at a wavelength of almost 1200 nm. The optical bandgaps estimated from the onset of absorption spectra are all in the range of 1.2 eV to 1.5 eV (Table 1), exhibiting a narrow bandgap property.

HOMO and LUMO energy levels of the copolymers are measured by cyclic voltammetry (CV). Gel permeation chromatography (GPC) was used to assess the molecular weight (Mₙ and M_{w}) and polydispersity (PDI). The CV and GPC results are listed in Table 1. With stronger electron-accepting 4FBTP, P4fBTPBDT showed both lower HOMO and LUMO energy levels than PtBTPBDT, indicating that copolymer electronic properties can be readily tuned by functionalization of the BTP units.

TABLE 1
Summary of structural, optical, and electronic properties of BTP based
copolymers

| | Mₙ | M_{w} | | HOMO | LUMO | E_{g} |
|---|---|---|---|---|---|---|
| | (KDa) | (KDa) | PDI | (eV) | (eV) | (eV) |
| PtBTP2T | 16.0 | 28.0 | 1.75 | | | 1.45 |
| PtBTPDPP | 61.9 | 130.5 | 2.10 | 5.07 | 3.86 | 1.21 |
| PcBTPBDT | 27.0 | 70.0 | 2.60 | 5.29 | 3.83 | 1.48 |
| PtBTPBDT | 70.0 | 133 | 1.90 | 5.29 | 3.83 | 1.46 |
| P4FBTPBDT | 53.0 | 106 | 2.00 | 5.42 | 3.97 | 1.45 |
| P4FBTPDTS | 20.0 | 78.0 | 3.80 | 5.09 | 3.70 | 1.39 |
| PtBTPIDT | 35.1 | 48.7 | 1.39 | 5.28 | 3.78 | 1.50 |

Photovoltaic Properties

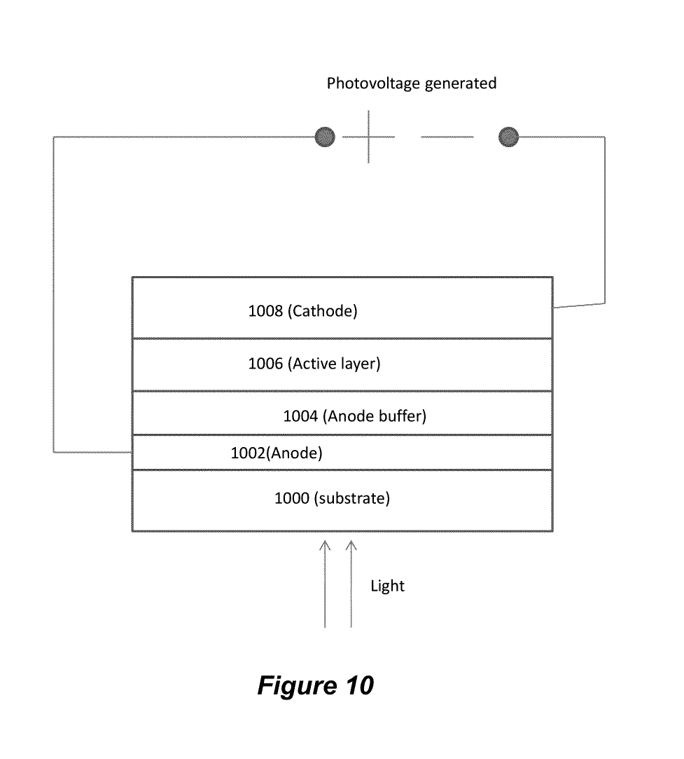

FIG. 10 illustrates a solar cell device structure according to one or more embodiments, comprising a substrate 1000, a transparent conductive anode layer 1002 (e.g., Indium Tin Oxide (ITO), Zinc Oxide (ZnO), or a combination of ZnO and ITO) on, above, or overlying the substrate 1000 (e.g., glass), a p-type or anodic interface/buffer layer or anode 1004 (e.g., PEDOT:PSS, Clevios VP AI 4083) on, above, or overlying the transparent conductive layer 1002, an active layer 1006 (e.g., interpenetrating phase-separated donor-acceptor network composite, or donor-acceptor heterojunction material, comprising the BTP based polymer and PCBM) on, above, or overlying the p-type interface layer, and a contact 1008 (e.g., metal contact such as Ca and/or Al or MoO₃ and Silver (Ag)) on, above, or overlying the active layer 1006. The BTP based polymer according to one or more embodiments can be the donor or the acceptor in the active layer 1006.

Photovoltaic properties of all the copolymers were investigated with either a conventional device configuration of FIG. 10 with ITO/PEDOT:PSS/polymer:PCBM/Ca/Al, or inverted device configuration of ITO/ZnO/polymer:PCBM/MoO₃/Ag. Copolymers were dissolved in chlorobenzene (CB) or 1,2-dichlorobenzene, with a total concentration of 24 milligrams per milliliter (mg/ml) of polymer and [6,6]-phenyl C61 butyric acid methyl ester (PC₆₁BM) or [6,6]-phenyl C71 butyric acid methyl ester (PC₇₁BM), for spin-coating of the active layers. Active layer thickness was controlled by varying spin rate. Various polymer/PCBM weight (wt) ratios (wt/wt) of 1:1, 1:2, 1:3, and 1:4 were evaluated and diiodooctane (DIO) of 0.5%-6% was added as a process additive to adjust film morphology. (See also Additional Information).

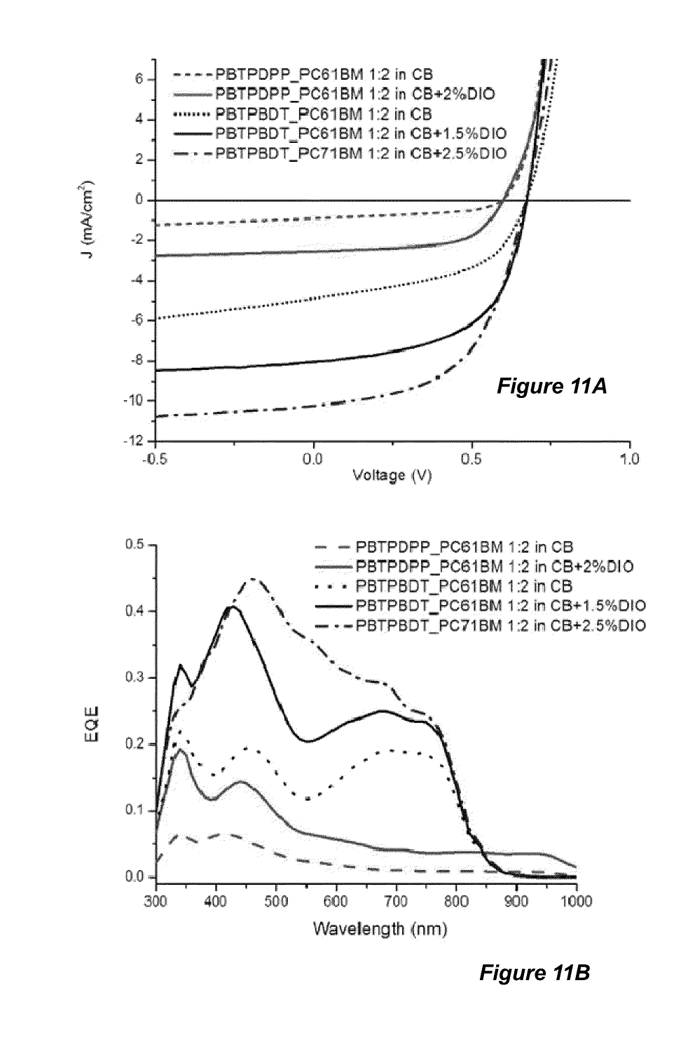

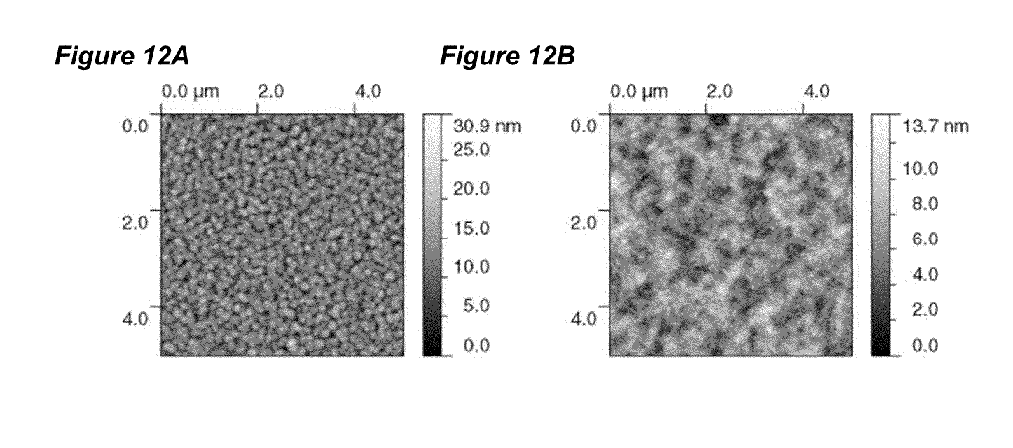

The first attempt at preparing PtBTPBDT solar cells with CB as the solvent and PC₆₁BM as acceptor in a convention device configuration, resulted in 0.9% power conversion efficiency. With diiodooctane (DIO) as an additive, device performance (efficiency η) increased to η=3.0%, V_{oc}=0.67 V, J_{sc}=7.9 mA/cm² and ff=0.56. The immediate improvement results from preferred film morphology, as shown in FIGS. 12A and 12B. Without the additive DIO, the polymer film shows sub-micrometer grain domains (FIG. 12A); with DIO, it exhibits a nanoscale phase separation (FIG. 12B). The External Quantum Efficiency (EQE) curve in FIG. 11B shows that PtBTPBDT has a substantial contribution to photo current generation at a wavelength between 500 nm and 850 nm.

Selected solar cell device characteristics with PtBTPBDT and PtBTPDPP as donor are summarized in Table 2. When PC₇₁BM is used as the acceptor, the average PtBTPBDT device efficiency further increased to 3.8% with 2.5% of DIO added; the highest efficiency is 4.1%. The improvement solely comes from increasing J_{sc} from 7.9 mA/cm² to 10.2 mA/cm², due to the stronger light absorption of PC₇₁BM. V_{oc} of all the PtBTPBDT devices is around 0.7V, but device J_{sc} and ff highly depend on donor/acceptor ratio, processing solvents and additives, film thicknesses, and annealing conditions.

Optimized solar cell device characteristics of all the copolymers are summarized in Table 2. When PcBTPBDT was used as electron donor, devices showed similar V_{oc} around 0.66 V. However, device J_{sc} is lower than devices using PtBTPBDT as the donor. This could be due to various reasons, such as lower molecular weight, different molecular packing, non-ideal morphology, etc. We can tell that device V_{oc} highly depends on the HOMO level of the donor polymers. Devices with P4FBTPBDT as donor give a much higher V_{oc} than devices with PtBTPBDT as donor.

TABLE 2
Summary of optimized solar cell device parameters prepared with BTP based
copolymers as donor (where *Acceptor is PC₆₁BM, ^{#}acceptor
is PC₇₁BM; D:A ratio is Donor:Acceptor ratio)

| | D:A | | | | | |
|---|---|---|---|---|---|---|
| | ratio | | | Jsc | | |
| Donor | (w:w) | Solvent | Voc (V) | (mA/cm²) | ff | PCE (%) |
| *PtBTP2T | 1:2 | ODCB | 0.76 ± 0.00 | 3.50 ± 0.04 | 0.34 ± 0.00 | 0.90 ± 0.01 |
| | | +10% DIO | | | | |
| *PtBTPDPP | 1:2 | CB | 0.60 ± 0.01 | 2.47 ± 0.12 | 0.61 ± 0.01 | 0.91 ± 0.03 |
| | | +2% DIO | | | | |
| *PcBTPBDT | 1:2 | CB | 0.66 ± 0.01 | 3.40 ± 0.09 | 0.53 ± 0.02 | 1.19 ± 0.04 |
| | | +4.0% DIO | | | | |
| *PtBTPBDT | 1:2 | CB | 0.67 ± 0.00 | 7.93 ± 0.14 | 0.56 ± 0.01 | 2.98 ± 0.13 |
| | | +1.5% DIO | | | | |
| ^{#}PtBTPBDT | 1:2 | CB | 0.68 ± 0.00 | 9.09 ± 0.47 | 0.63 ± 0.01 | 3.88 ± 0.14 |
| | | +2.5% DIO | | | | |
| *P4FBTPBDT | 1:2 | CB | 0.80 ± 0.01 | 3.34 ± 0.17 | 0.57 ± 0.02 | 1.50 ± 0.06 |
| | | +4% DIO | | | | |
| ^{#}P4FBTPBDT | 1:2 | CB | 0.83 ± 0.00 | 5.79 ± 0.05 | 0.64 ± 0.01 | 3.07 ± 0.04 |
| | | +3% DIO | | | | |
| *P4FBTPDTS | 1:2 | CB | 0.67 ± 0.00 | 5.74 ± 0.04 | 0.55 ± 0.00 | 2.12 ± 0.02 |
| | | +4% DIO | | | | |
| ^{#}P4FBTPDTS | 1:2 | CB | 0.68 ± 0.00 | 6.54 ± 0.14 | 0.60 ± 0.01 | 2.67 ± 0.04 |
| | | +2% DIO | | | | |
| *PtBTPIDT | 1:2 | CB | 0.80 ± 0.00 | 6.89 ± 0.06 | 0.43 ± 0.00 | 2.36 ± 0.03 |
| ^{#}PtBTPIDT | 1:4 | ODCB | 0.77 ± 0.01 | 10.01 ± 0.17 | 0.45 ± 0.01 | 3.46 ± 0.18 |

As shown above, due to their electron accepting property, BTP small molecules may be used as an electron acceptor in organic solar cell devices, or as an electron conductor in OFETs. After copolymerization with various donor units, BTP copolymers are expected to have an ambipolar property and can be used as either an electron donor or an electron acceptor.

Photovoltaic properties of BTP based small molecules and copolymers, including pure tBTP, 1:1 (w/w) mixture of cBTP and tBTP, PtBTP2T, and PtBTPDPP, as acceptor, were investigated with a device configuration of ITO/PEDOT:PSS/donor:BTP/Ca/Al, using either regioregular poly(3-hexylthiophene) (P3HT) or tetrabenzoporphyrin (BP) as donor.

When BP is used as a donor in a bilayer device structure, a mixture of tBTP and cBTP worked much better than the pure tBTP as acceptor, due to the much better film uniformity of mixed tBTP and cBTP. As a result, device efficiency as high as 0.86% with improved V_{oc}, J_{sc}, and ff was achieved. The higher device V_{oc} as compared to a BP/PCBM device is due to the higher LUMO level of BTP as compared to PCBM (see also Additional Information).

In addition, BTP based copolymers PtBTPDPP and PtBTP2T demonstrated an electron accepting property in a bilayer solar cell device (same structure as described in FIG. 10, except the active layer has a donor/acceptor bilayer heterojunction structure, not a bulk heterojunction). With BP as donor, moderate device efficiencies of about 0.5-0.6% were achieved.

OTFT Properties

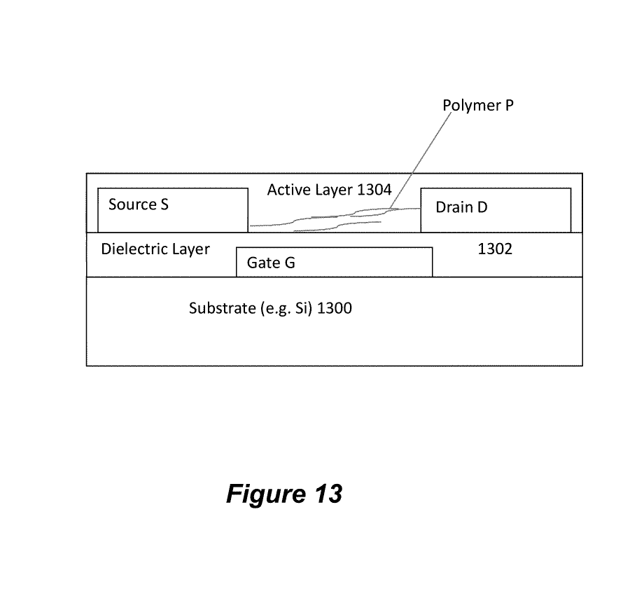

FIG. 13 illustrates an organic transistor structure, according to one or more embodiments, comprising a substrate 1300 (e.g., n-type Silicon (Si)), a dielectric layer 1302 (e.g., SiO₂, passivated dielectric layer such as passivated SiO₂) on the substrate, an active layer 1304 comprising BTP copolymer P on or above the dielectric layer 1302, source S and drain D contacts (e.g., gold (Au) contacting the active layer 1304), and a Gate G separated from the active layer 1306 by the dielectric layer 1302. The active layer 1304 can include an n-type and/or p-type BTP based polymer according to one or more embodiments of the present invention. In one or more embodiments, the gate G is the substrate (e.g., n-type Si) and a separate gate layer is not required).

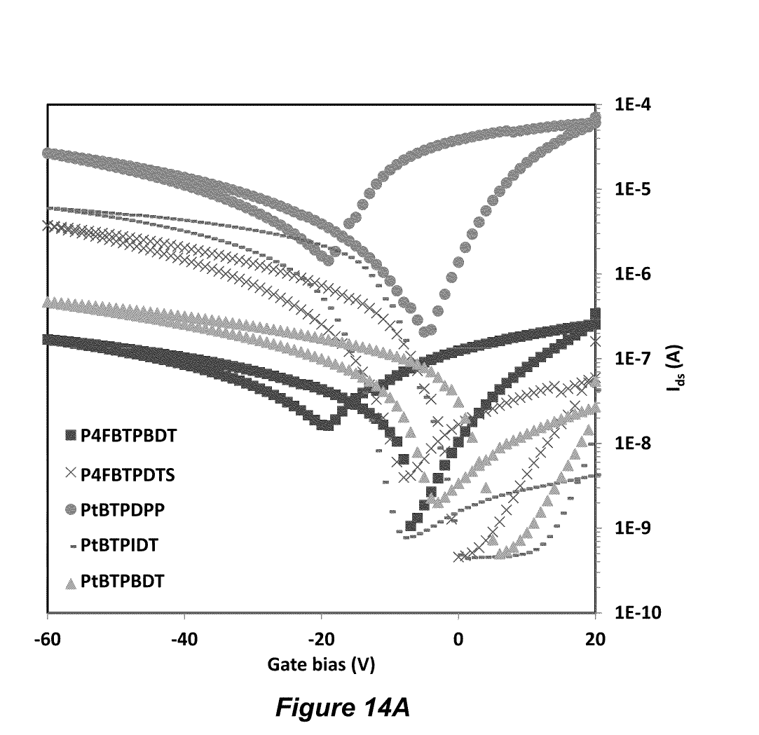

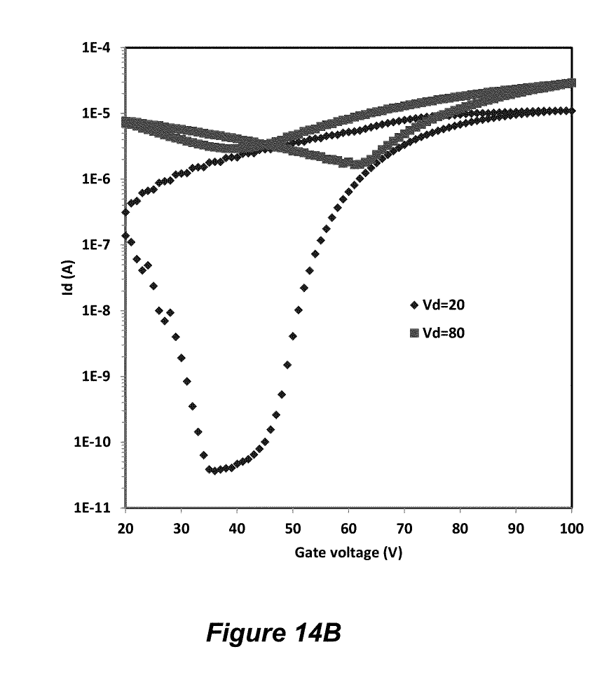

FIG. 14 shows transfer characteristics of such OTFT devices with BTP based copolymer films. The bottom gate, bottom contact FETs measured in FIGS. 14A-B were fabricated with a Si/SiO₂/Au/passivation layer/BTP copolymers structure, as illustrated in FIG. 13, by spin-coating from polymer solution on a highly n-doped silicon wafer and preparing 300 nm thick thermally-grown SiO₂ gate dielectrics passivated by DTS-10 (see also Additional Information). The prepared devices were then tested (results shown in FIG. 14A-B). All the copolymers exhibit ambipolar charge transporting properties and reasonably good hole mobility, with PtBTPDPP and P4FBTPDTS showing the highest values up to 0.09 cm²/Vs. It is interesting to note that both PcBTPBDT and PtBTPBDT devices showed very similar hole mobility, considering their very different molecular conformation. The ambipolarity was clearly shown in output curves obtained for PtBTPDPP and P4FBTPBDT. Since the PtBTPDPP device showed the highest hole mobility and quite high electron current, n-type transfer characteristics of an OTFT device with PtBTPDPP copolymer, in both the linear (V_{d}=20V) and saturation (V_{d}=80V) regime, were collected and are shown in FIG. 14B. As expected, the device was turned on at relatively high gate voltage (˜40V) due to the injection barrier from Au to the LUMO of the polymer. The hysteresis was also higher compared to hole current transfer curves, implying that electron traps were more significant compared to hole traps in this device. Saturation electron mobility, calculated from this transfer curve (at V_{d}=80V) is ˜9.0×10⁻² cm²/Vs, which is comparable to its hole mobility. It is obvious that the polymer mobility is affected by both the donor and acceptor units, but the results prove that BTP can be a good building block for high mobility semiconducting polymers (Table 3). Higher mobility can be expected with further device and polymer structure optimization. It is also worth noting that all the devices have good on/off ratios.

TABLE 3
Summary of field effect transistor properties of BTP based copolymers.

| | Hole Mobility | V_{T} | |
|---|---|---|---|
| | (cm²/V · s) | (V) | On/Off |
| PtBTPDPP | 8.9 × 10⁻² | 1.4 | 10⁶ |
| PcBTPBDT | 6.1 × 10⁻⁴ | −6.3 | 10⁴ |
| PtBTPBDT | 6.4 × 10⁻⁴ | 0 | 10⁴ |
| P4FBTPBDT | 3.4 × 10⁻⁴ | 24.1 | 10³ |
| P4FBTPDTS | 1.0 × 10⁻² | −16.1 | 10⁵ |
| PtBTPIDT | 6.8 × 10⁻³ | 8.0 | 10⁵ |

As discussed above, an exemplary semiconducting FET that utilizes the conjugated polymer compositions disclosed herein comprises a source electrode S, a drain electrode D, a gate electrode G, and an electronically insulating layer of material forming a gate electrode dielectric. Polymer layers may be deposited on a surface by a number of methods, such as inkjet printing, bar coating, spin coating, blade coating, and the like. Thin film deposition techniques, such as spin coating, spray coating, bar coating, roll coating, blade coating, dip coating, free span coating, dye coating, screen printing, or ink jet printing may be used. As noted below, embodiments of the invention can, for example, use inkjet printing to form partially or fully treated surfaces, wherein differences in the surface treatments (e.g. that result in surfaces having different surface energies) are used in order to form barrier regions that confine the polymeric compositions.

Process Steps

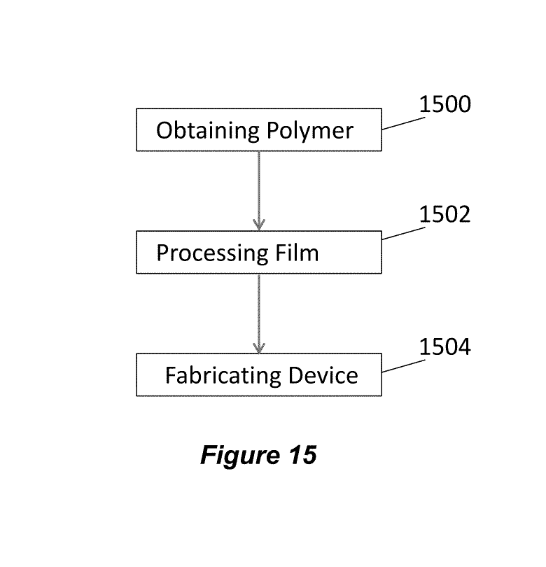

FIG. 15 illustrates a method of fabricating a composition of matter and/or an organic device comprising the composition of matter.

Block 1500 represents fabricating or obtaining a polymer (I). The polymer can have the following structural formula:

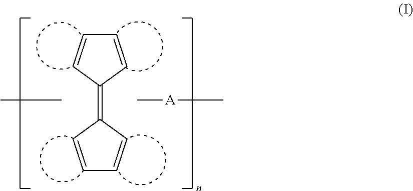

where

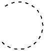

represents mono-cyclic or polycyclic aromatic rings fused to the fulvalene core, with or without substituents, wherein the four rings are the same or different; and A is a monomer. The polymer I can be in a mixture with one or more fullerene derivatives.

The rings can be at least one compound chosen from acridine, anthracene, azaborinine, azaphosphinine, benzene, benzofuran, benzimidazole, benzothiazole, carbazole, β-carboline, cinnoline, isobenzofuran, benzothiophene, borole, furan, furazan, germole, imidazole, indazole, indole, indolizine, isoindole, isoquinoline, isothiazole, isoxazole, naphthalene, naphthyridine, oxadiazole, oxazole, phenanthridine, phenanthroline, phenazine, phosphole, phthalazine, pteridine, purine, pyrazine, pyrazole, pyridazine, pyridine, pyrimidine, pyrrole, quinoline, quinoxaline, quinazoline, silole, tetrazole, thiadiazole, thiazole, triazine, (1,2,3,)- and (1,2,4)-triazole, and thiophene.

The fabricating can comprise fabricating the polymer having the following structural formula (including enantiomers of the sulfur containing compound):

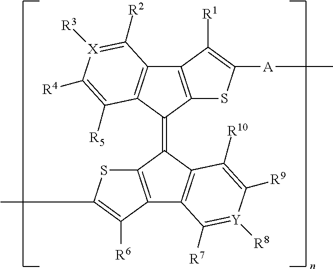

wherein X and Y are at least one unit chosen from C and N; A is a monomer; and R¹-R¹⁰ are at least one member chosen from hydrogen, a halogen, an alkyl, a cyclic alkyl, a heterocyclic, an alkyloxy, an alkylthio, an alkenyl, an alkynyl, an aryl, an aryloxy, an arylthio, a heteroaryl, a fluoroaryl, an amido, an amino, an acyl, a carboxyl, a cyano, an epoxy, a carboxylate, a nitro, a carbonyl, a sulfonyl, a sulfinyl, a cyano, a hydroxyl, a thiol, a silyl, a siloxy, a silyloxy, an azo, a boryl, a phosphoryl, a phosphinyl, and R² and R¹⁰ can equal to nothing when X or Y is nitrogen.

The polymer can comprise repeating units chosen from PtBTP2T, PtBTPDPP, PtBTPBDT, P4FBTPBDT, P4FBTPDTS, and PtBTPIDT.

The fabricating can comprise fabricating the polymer having the following structure:

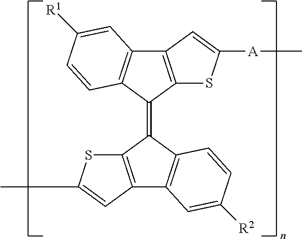

wherein A is a monomer; and R¹-R² are at least one member chosen from hydrogen, a halogen, an alkyl, a cyclic alkyl, a heterocyclic, an alkyloxy, an alkylthio, an alkenyl, an alkynyl, an aryl, an aryloxy, an arylthio, a heteroaryl, a fluoroaryl, an amido, an amino, an acyl, a carboxyl, a cyano, an epoxy, a carboxylate, a nitro, a carbonyl, a sulfonyl, a sulfinyl, a cyano, a hydroxyl, a thiol, a silyl, a siloxy, a silyloxy, an azo, a boryl, a phosphoryl, or a phosphinyl.

The polymer can comprise a donor and an acceptor, wherein A comprises the donor and B comprises acceptor, or A comprises the acceptor and B comprises the donor, where B has the formula (and enantiomers thereof) of the left hand compound in the unit, i.e. B has the formula:

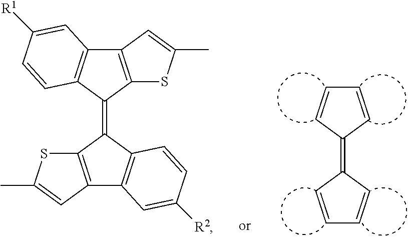

The polymer can be in a mixture with one or more fullerene derivatives.

The polymer can comprise a plurality of (E)-8,8′-biindeno[2,1-b]thiophenylidene (BTP) units, each BTP unit having a nonplanar twisted structure having a splay angle (e.g., about 20 degrees) between proximal aromatic rings; the BTP units arranged in a monoclinic lattice with a sulfur-sulfur distance (e.g., 3.4 Å); and within the monoclinic lattice, the BTP units stacking themselves in a fully eclipsed fashion (e.g., with an intermolecular distance in the stack is about 3.5 Å). The splay angle may be such that the BTP is soluble in at least one solvent chosen from THF, dichloromethane, ethyl acetate, and hexane.

The polymer's backbone may be sufficiently rigid such that absorption profiles of the polymers in solution and film state are essentially identical.

The fabricating can comprise fabricating the polymer comprising a copolymer with at least one monomer chosen from diketopyrrolopyrrole (DPP), dithienylsilole (DTS) or benzodithiophene (BDT).

The fabricating can comprise Suzuki-Miyaura coupling methyl 2-bromobenzoate to form compound x; hydrolyzing the compound x to form compound y; performing a Friedel-Crafts reaction on compound y to afford a ketone; synthesizing BTP from the ketone by Lawesson's reagent; selecting one or more isomers of the BTP; and brominating and stannylating the isomers and performing polymerization reactions on the brominated and stannylated isomers to form the polymer.

The fabricating can comprise functionalizing the polymer, e.g., wherein the polymer has an optical bandgap in a range of 1.21-2.10 eV (e.g., at most 1.5 eV). The polymer can be functionalized or copolymerized, wherein the polymer has a peak absorption at a wavelength between 600 nm and 900 nm. The polymer can be functionalized for solution casting on a device substrate, wherein the device is an organic light emitting device, organic light emitting diode, organic transistor, or organic photovoltaic device.

Block 1502 represents processing the polymer on, above, onto, or overlying a substrate. The processing can comprise dissolving the polymer in a solvent to form a solution, and spin coating the solution as a film on the substrate. The processing onto the substrate can be in the presence of an additive, and the film can be annealed after the coating.

A carrier mobility of the film can be based on a controlled isomeric structure of the polymer in the film. The fabrication of the film can include isomerically tuning the polymer chains in the film. For example, the film can comprise one or more polymer chains comprising an isomerically tuned linear polymer, the isomerically tuned linear polymer having an amount of compound comprising a trans isomer structure adjusted relative to an amount of cis-isomer of the compound in the film, such that the film's carrier mobility is isomerically tuned.

For example, the processing can include processing or fabricating a film comprising a polymer (I), wherein the polymer (I) has the following structural formula:

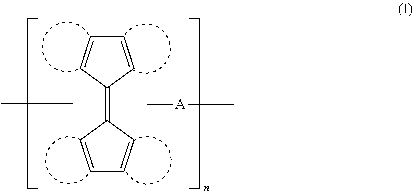

where

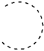

represents mono-cyclic or polycyclic aromatic rings fused to the fulvalene core, with or without substituents, wherein two of the rings comprise thiophene rings having Sulfur atoms positioned to form a trans isomer structure; an amount of the compound comprising the trans isomer structure is adjusted relative to an amount of cis-isomer of the compound in the film, such that the film's carrier mobility is isomerically tuned; and A is a monomer.

For example, the processing of the film can include selecting/adjusting an amount of the compound B having the structural formula (including enantiomers thereof):

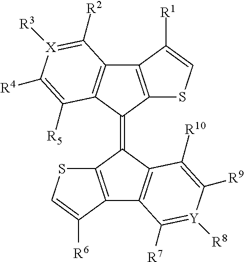

wherein the amount of the compound B is adjusted, controlled, or tuned relative to an amount of cis-isomer of B in the film, such that the film's carrier mobility (e.g., hole or electron mobility) is adjusted, controlled, or tuned. For example, the carrier mobility can be increased as compared to a carrier mobility of a control film where an amount of B is not adjusted relative to the amount of the cis-isomer.

In addition, the donor/acceptor ratio in the polymer, the film's thickness, the composition of the solvent and/or additive, and the amount of B can be effective/sufficient to achieve a desired/threshold carrier mobility (e.g., electron or hole mobility of at least 0.09 V/cm²) and/or photovoltaic efficiency. Verification of the desired mobility or photovoltaic efficiency can be achieved by fabricating the films in transistor or solar cell devices and measuring the electron or hole mobility and/or photovoltaic performance as described in this disclosure. Modifications to the polymer structure, solvents (as described above) can be made until the desired performance is achieved.

Thus, one or more embodiments of the invention disclose means (isomeric tuning, polymer functionalizing, selection of polymer composition and/or donor acceptor ratio, selection of film thickness, and statutory equivalents thereof) to adjust (or means for adjusting) carrier mobility and/or photovoltaic efficiency/performance of the polymer chains comprising the active region (e.g., conductive channel or light absorbing region) of a device.

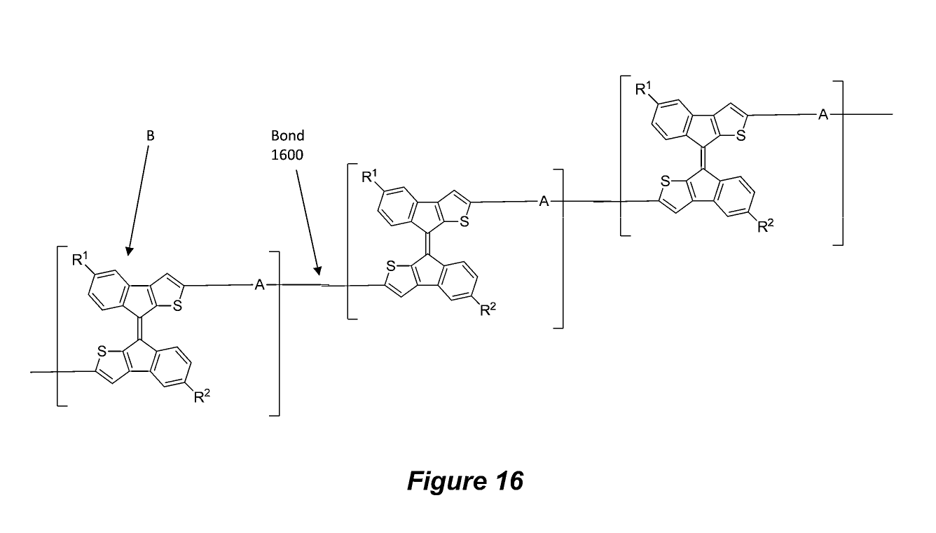

For example, the polymer can comprise units bonded in a linear chain B-A-B-A, e.g., the isomerically tuned linear polymer can have the structure of FIG. 16 where compound B (on the left side in each unit) is the donor and monomer A is the acceptor, or B is the acceptor and A is the donor. The bond 1600 between units is also shown in FIG. 16.

Block 1504 represents fabricating an organic device comprising the film of Block 1502. The organic device can comprise a photovoltaic device, wherein fabrication comprises depositing transparent conductive layer 1002 on, above, or overlying a substrate 1000, depositing (e.g., spin coating) a p-type interface layer 1004 on, above, or overlying the transparent conductive layer 1002, depositing (e.g. spin coating) the polymer as a film (e.g., comprising the active layer 1006 comprising the functionalized or copolymerized polymer fabricated in Block 1500 and processed as in Block 1502) on, above, or overlying the p-type interface layer 1002, and depositing (e.g. evaporating) contacts 1008 on, above, or overlying the active layer 1006. Thus, the active region can produce electrical power in response to incident electromagnetic radiation. The polymer can be electrically connected to transfer charge, photogenerated (by light illumination) in the polymer, to the contacts via the interface layers.

Such a photovoltaic cell structure can include the active region combined in a film on or above the substrate, the film having a structure, crystallinity, morphology, and thickness, donor/acceptor ratio, and isomer ratio/amount of the polymer, wherein, measured at 1 sun (AM 1.5G), the photovoltaic cell has an open circuit voltage V_{oc} of at least 0.7 V or in a range 0.54 V-0.79 V; a short circuit voltage J_{sc} of at least 8 mA/cm² or in a range 0.81-10.2 mA/cm²; a fill factor ff of at least 0.65 or in a range of 0.29-0.65; and an efficiency η of at least 4.1% or in a range of 1-4.1%. The selected polymer can be functionalized to have an optical bandgap of at most 1.5 eV.

The device can comprise an organic transistor, wherein the fabricating comprises depositing (e.g., thermally growing) a dielectric layer 1302 on a substrate 1300 (e.g., n-type silicon), passivating the dielectric 1302, depositing (e.g., spin casting) the active region 1304 or film comprising the polymer or polymer chains P (e.g., in solution) fabricated in Block 1502 onto the passivated dielectric, and depositing source, drain, and gate electrodes (if the substrate 1000 is a gate, a separate gate layer may not be necessary). The film comprising the polymer can comprise a conductive channel, wherein the source and drain contacts electrically contacting the film pass a current through the conductive channel between the source contact and the drain contact (e.g., the polymer chain(s) P comprising the polymer are electrically connected such that current passes between source and drain), and the gate controls the current's flow when a bias is applied across the dielectric layer between the conductive channel and the gate. The substrate, source contact, the drain contact, the gate, the dielectric layer, and the film can be effective to achieve the desired carrier mobility (e.g., hole mobility of at least 0.09 cm²/Vs).

The device can comprise an organic FET comprising a polymer prepared in Block 1500, wherein the polymer comprises a donor and an acceptor, A comprises the donor and compound B comprises acceptor, or A comprises the acceptor and compound B comprises the donor, and the FET has an electron and/or hole mobility of at least 0.09 cm²/Vs.

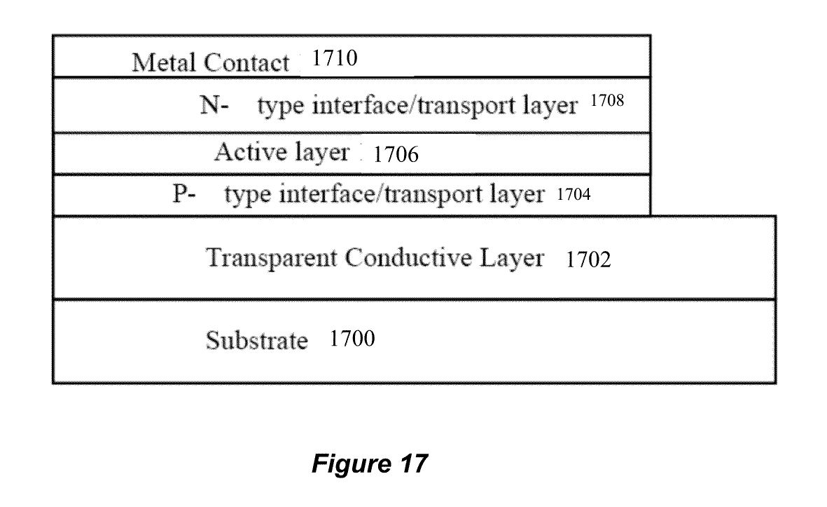

The device can comprise an optoelectronic device, an organic light emitting diode (OLED), comprising an active layer including the BTP based polymer according to one or more embodiments of the present invention, as illustrated in FIG. 17. The OLED comprises a substrate 1700, a transparent conductive layer 1702 (e.g., ITO) on, above, or overlying the substrate 1700 (e.g., glass, plastic), a p-type hole transport layer 1704 on, above, or overlying the transparent conductive layer 1702, the active or emission layer 1706 on, above, or overlying the p-type hole transport layer 1704, an n-type electron transport layer 1708 on, above, or overlying the active layer 1706, and a metal contact 1710 to the n-type transport layer 1708.

Additional Information

Solar Cell Fabrication

The general procedure for fabricating conventional polymer/PCBM devices (e.g., polymer donor/PCBM acceptor, or polymer donor/BTP acceptor devices) was as follows. ITO substrates were sonicated for 20 minutes each in soap water, deionized water, acetone, and isopropanol and kept in isopropanol until use. PEDOT:PSS (Clevios P VP A14083) was filtrated with a 0.45 μm PTFE filter and spin-coated onto the ITO substrate with a layer thickness about 30 nm, then baked on a hotplate at 120° C. for 10 minutes, and immediately transferred to a glove box. PEDOT:PSS coated ITO substrates were baked again at 195° C. for 3 minutes before use.

Polymer/PCBM or polymer/BTP solutions of various ratio and concentration in chlorobenzene or dichlorobenzene, with 0-6% (v/v) diiodooctane as additive, were filtered with a 0.45 μm PTFE filter and spin-coated onto the PEDOT:PSS coated ITO substrate, to achieve the desired film thickness. The films were dried at room temperature for 20 minutes and selected films were annealed at various temperatures to completely remove residue solvent and fine tune film morphology. In one embodiment, polymer/PCBM solutions of 24 mg/ml in chlorobenzene were filtered with a 0.45 μm PTFE filter and spin-coated onto the PEDOT:PSS coated ITO substrate to achieve the desired film thickness. The films were dried at room temperature for 30 minutes, then annealed at 50° C. for 10 minutes to completely remove residue DIO. Then, Ca (20 nm thick)/Al (70 nm thick) was thermally evaporated as the cathode at a pressure of ˜10⁻⁷ torr, using a shadow mask with an active area of ˜6 millimeters squared (mm²). The Current density-Voltage (J-V) characteristics were measured at 1 sun (AM 1.5G) in a N₂-filled glovebox equipped with a Xenon lamp (Newport) and Keithley 2408 SMU.

The general procedure to fabricate inverted bulk heterojunction polymer:fullerene devices was as follows. ITO substrates were sonicated for 20 minutes each in soap water, deionized water, acetone, and isopropanol and kept in isopropanol until use. The ZnO precursor was prepared by dissolving zinc acetate dihydrate (Zn(CH₃COO)₂.2H₂O, 1 gram (g)) and ethanolamine (NH₂CH₂CH₂OH, 0.28 g) in 2-methoxyethanol (CH₃OCH₂CH₂OH, 10 milliliters (mL)) under vigorous stirring for 12 hours (h) for the hydrolysis reaction in air. The ZnO precursor solution was spin-cast on top of the ITO-glass substrate and annealed at 200° C. for 1 hour in air, then the ZnO-coated substrates were transferred into a glove box. Polymer: fullerene (FLN) solutions dissolved in 1 ml of o-dichlorobenzene (ODCB) or chlorobenzene (CB) at 80° C. were filtered with a 0.45 μm PTFE filter and spin-coated onto the ITO substrate at a desired spin rate. The films may be further annealed under different conditions to optimize the device performance. Then, a thin layer of MoO₃ film (6 nm thick) was evaporated on top of the active layer. Finally, the anode (Ag, ≈60 nm thick) was deposited through a shadow mask by thermal evaporation in a vacuum of about 3×10⁻⁶ Torr.

The general procedure for fabricating BP donor/BTP acceptor devices is as following: ITO substrates were sonicated for 20 minutes each in soap water, deionized water, acetone, and isopropanol and kept in isopropanol until use. PEDOT:PSS (Clevios P VP A14083) was filtrated with a 0.45 μm PTFE filter and spin-coated onto a ITO substrate with a layer thickness about 40 nm, then baked on a hotplate at 120° C. for 10 minutes, and then immediately transferred to a glove box. PEDOT:PSS coated ITO substrates were baked again at 195° C. for 3 minutes before use. A solution of BP precursor (15 mg/ml in chloroform/chlorobenzene (1:2 v/v)) was filtered with a 0.2 μm PTFE filter and spin-coated onto the ITO substrate at a spin rate of 1500 revolutions per minute per second (rpm/s) for 30 seconds (s). Then, the films were annealed at 185° C. for 20 minutes on a hotplate under a petri-dish to fully convert the precursor to BP. Solutions of BTP small molecule or polymer (10 mg/ml in chlorobenzene) were filtered with a 0.2 μm PTFE filter and spin-coated onto the ITO/PEDOT:PSS/BP substrate at a spin rate of 1500 rpm/s for 45 s. Finally Ca (20 nm thick)/A1 (70 nm thick) were thermally evaporated as the cathode at a pressure of ˜10⁻⁷ torr, using a shadow mask with an active area of ˜6 mm². The J-V characteristics were measured at 1 sun (AM 1.5G) in a N₂-filled glovebox equipped with a Xenon lamp (Newport) and Keithley 2408 SMU.

The average J_{sc}, V_{oc}, ff and efficiency of each device fabrication condition is shown in Table 2. Each number is averaged from 5 devices fabricated and tested under the same condition. The errors are also given in Table 2. Power conversion efficiency (PCE) η is calculated using the following equation 1:

PCE (%)=V_{oc}*J_{sc}*ff/Pinc (equation 1),

where V_{oc} is the open circuit voltage (V) (device voltage when no external electric current flows between the terminals); J_{sc} is the short circuit current density (mA/cm²) (the current of the solar cell when the voltage across the solar cell is zero, i.e., when the solar cell is short circuited); ff is fill factor (the ratio of maximum obtainable power to the product of the open-circuit voltage and short-circuit current); and Pinc is the intensity of incident light (mW/cm²).

Further information on one or more embodiments of the invention can be found in [27].

OFET Device Fabrication

BTP copolymers were dissolved in chloroform with a concentration of 8 mg/ml. Heavily doped n-type silicon substrates with 300 nm thermally grown SiO₂ were prepared as the bottom gate electrode. Au (gold) was deposited for bottom source and drain electrodes. After SiO₂ dielectric was passivated by DTS10 (decyl(trichlorosilane)), all six polymers were spun onto substrates at a spin rate of 2000 revolutions per minute (rpm) for 30 seconds. Coated substrates were sequentially heated at 150° C. for 8 minutes (min). The SiO₂ and DTS are the gate layer. Devices were tested on a Signatone probe station inside a nitrogen glovebox with an atmosphere having <1 parts per million (ppm) oxygen concentration. Data were all collected by a Keithley 4200 system. Mobility was extracted from the saturation regime using the following equation,

$${I}_{D} = \frac{1}{2} μ C \frac{W}{L} {( {V}_{G} - {V}_{T} )}^{2} \qquad equation 2$$

where W is the channel width (1 millimeter), L is the channel length (80 micrometers), μ is the carrier mobility, V_{G} is the gate voltage, and V_{T} is the threshold voltage. The capacitance, C, of the SiO₂ is 14 nano Farads per centimeter square (nF/cm²). In equation 2 and FIGS. 14A-B, I_{d} is the drain current entering to the polymer films from the source and flowing to the drain, V_{d} is the drain voltage (in volts) with respect to the source, and V_{G} is the gate voltage or gate bias with respect to the source.

### Synthesis Examples

### Synthesis of Methyl 2-(thiophen-3-yl)benzoate (3a)

24 ml THF and 6 ml H₂O were added to a 50 ml two-necked round-bottomed flask, and the solution was bubbled with argon for 20 minutes. Na₂CO₃ (17.8 g, 168 millimoles (mmol)), Pd(PPh₃)₂Cl₂ (1.5 g, 2.1 mmol), Methyl 2-bromobenzoate (12 g, 56 mmol), and 3-thienyl boronic acid (8.6 g, 67 mmol) were then added to the solution, and the mixture was stirred at 70° C. overnight. The solution was then cooled to room temperature and washed sequentially with H₂O and brine. After chromatography on a silica gel column (30% CH₂Cl₂:Hexane), methyl 2-(thiophen-3-yl)benzoate was isolated as a colorless oil in 92% yield. ¹H-NMR (600 MHz, CDCl₃), δ (ppm): 7.76 (d, J=7.7 Hz, 1H), 7.49 (t, J=7.5 Hz, 1H), 7.38 (t, J=6.2 Hz, 1H), 7.33 (dd, J=3.0, 4.9 Hz, 1H), 7.23 (dd, J=3.0, 1.3 Hz 1H), 3.71 (s, 15H); ¹³C-NMR (150 MHz, CDCl₃) δ (ppm): δ 169.13, 141.36, 136.72, 131.21, 130.92, 130.55, 129.53, 128.39, 127.21, 124.98, 122.20, 52.06; HRMS (ESI+) cald. For C₁₂H₁₀O₂S₁Na: 241.0299, found: 241.0288.

### Methyl 4-methyl-2-(thiophen-3-yl)benzoate (3b)

¹H-NMR (600 MHz, CD₂Cl₂), δ (ppm): 7.67 (d, J=7.9 Hz, 1H), 7.37-7.30 (d, 1H), 7.24 (s, 2H), 7.20 (d, J=8.3 Hz, 1H), 7.07 (d, J=5.1 Hz, 1H), 3.68 (s, 3H), 2.40 (s, 3H); ¹³C-NMR (150 MHz, CD₂Cl₂): δ 168.66, 141.83, 141.62, 136.69, 131.32, 129.65, 128.53, 127.95, 127.85, 124.69, 122.01, 51.71, 21.05.; HRMS (EI+) cald. for C₁₃H₁₂O₂S₁: 232.0558, found: 232.0556.

### Methyl 2-(thiophen-3-yl)-4-(trifluoromethyl)benzoate (3c)

¹H-NMR (600 MHz, CD₂Cl₂), δ (ppm): 7.85 (d, J=8.1 Hz, 1H), 7.72 (s, 1H), 7.66 (d, J=7.8 Hz, 1H), 7.41 (dd, J=5.0, 3.0 Hz, 1H), 7.35 (dd, J=3.0, 1.4 Hz, 1H), 7.12 (dd, J=4.9, 1.3 Hz, 1H); ¹³C NMR (150 MHz, CD₂Cl₂): δ 167.96, 139.78, 137.09, 134.49, 132.54 (q, J=32.6 Hz), 129.83, 128.00, 127.21 (q, J=3.8 Hz), 125.68, 123.87 (q, J=3.7 Hz), 123.23, 52.28.; HRMS (EI+) cald. for C₁₃H₉O₂F₃S₁: 286.0275, found: 186.0271.

### Methyl 4-fluoro-2-(thiophen-3-yl)benzoate (3d)

¹H-NMR (600 MHz, CD₂Cl₂), δ (ppm): δ 7.81 (dd, J=8.6, 5.9 Hz, 1H), 7.37 (dd, J=5.0, 3.0 Hz, 1H), 7.29 (dd, J=3.0, 1.3 Hz, 1H), 7.14 (dd, J=9.6, 2.7 Hz, 1H), 7.12-7.05 (m, 2H).; ¹³C NMR (150 MHz, CD₂Cl₂): δ 167.77, 164.73, 163.06, 140.29, 140.28, 139.66, 139.60, 132.13, 132.07, 128.20, 127.09, 127.07, 125.18, 122.84, 117.47, 117.32, 114.16, 114.01, 51.94; HRMS (EI+) cald. for C₁₂H₉O₂F₁S₁: 236.0307, found: 236.0317.

### Methyl 2-fluoro-6-(thiophen-3-yl)benzoate (3e)

¹H-NMR (600 MHz, CD₂Cl₂), δ (ppm): δ 7.48-7.40 (m, 1H), 7.37 (dd, J=3.0, 1.4 Hz, 0H), 7.28 (dd, J=7.8, 1.1 Hz, 1H), 7.18 (dd, J=4.9, 1.4 Hz, 0H), 7.12 (ddd, J=9.3, 8.4, 1.0 Hz, 1H); ¹³C NMR (150 MHz, CD₂Cl₂): δ 166.11, 160.28, 158.63, 139.38, 139.37, 136.49, 136.47, 131.22, 131.16, 127.54, 126.16, 125.10, 125.08, 123.12, 121.31, 121.19, 114.43, 114.29, 52.45. HRMS (EI+) cald. for C₁₂H₉O₂F₁S₁: 236.0307, found: 236.0309.

### Methyl 3-(benzo[b]thiophen-3-yl)benzoate (3f)

¹H NMR (600 MHz, CD₂Cl₂), δ (ppm): 7.97 (d, J=7.8 Hz, 1H), 7.93 (d, J=8.0 Hz, 1H), 7.62 (t, J=7.5 Hz, 1H), 7.52 (t, J=7.7 Hz, 1H), 7.48 (d, J=7.6 Hz, 1H), 7.45 (d, J=7.9 Hz, 1H), 7.41-7.30 (m, 3H); ¹³C NMR (125 MHz, CD₂Cl₂) δ (ppm): 181.82, 167.84, 139.57, 138.95, 137.16, 136.02, 131.70, 131.60, 131.56, 130.02, 127.86, 124.22, 124.20, 123.33, 122.66, 122.21, 51.82. HRMS (EI+) cald. for C₁₆H₁₂O₂S₁: 268.0558, found: 268.0551.

### Synthesis of 2-thiophen-3-yl benzoic acid (4a)

Compound 2a (8 g, 36.6 mmol) dissolved in 55 ml EtOH was added into 4N NaOH_{(aq)} (55 ml). The mixture was heated to 90° C. and stirred for 2 h. The solution was cooled to room temperature and then added into iced-cold concentrated Hydrochloric acid (HCl). White precipitate came out and was filtered. After being washed with water (200 ml), the white solid was collected and dried in vacuum overnight for the next reaction. 98%. ¹H NMR (600 MHz, CDCl₃), δ (ppm): 10.20 (br, s, 1H), 7.91 (dd, J=7.8 Hz, 1H), 7.53 (t, J=7.6 Hz, 1H), 7.45-7.36 (m, 2H), 7.32 (dd, J=4.9, 3.0 Hz, 1H), 7.26 (dd, J=3.0, 1.3 Hz, 1H), 7.12 (dd, J=5.0, 1.3 Hz, 1H); ¹³C NMR (125 MHz, CDCl₃) δ (ppm): 141.07, 137.67, 132.07, 131.08, 130.50, 128.63, 127.30, 125.01, 122.58; MS (EI) cald. for C₁₁H₈S₁: 204.02, found: 204.03.

### 4-methyl-2-(thiophen-3-yl)benzoic acid (4b)

¹H NMR (600 MHz, CDCl₃), δ (ppm): 7.83 (d, J=8.6 Hz, 1H), 7.35 (dd, J=4.9, 3.0 Hz, 1H), 7.28 (dd, J=3.0, 1.3 Hz, 1H), 7.25 (s, 1H), 7.23 (s, 1H), 7.13 (dd, J=4.9, 1.3 Hz, 1H), 2.42 (s, 3H). HRMS (EI+) cald. for C₁₂H₁₀O₂S₁: 218.0402, found: 218.0399.

### 2-(thiophen-3-yl)-4-(trifluoromethyl)benzoic acid (4c)

¹H NMR (600 MHz, CDCl₃), δ (ppm): 8.01 (d, J=8.2 Hz, 1H), 7.73 (s, 1H), 7.70 (ddd, J=8.1, 1.8, 0.8 Hz, 1H), 7.42 (dd, J=4.9, 3.0 Hz, 1H), 7.39 (dd, J=3.0, 1.4 Hz, 1H), 7.18 (dd, J=4.9, 1.4 Hz, 1H). HRMS (EI+) cald. for C₁₂H₇O₂S₁F₃: 272.0119, found: 272.0117.

### 4-fluoro-2-(thiophen-3-yl)benzoic acid (4d)

¹H NMR (600 MHz, CDCl₃), δ (ppm): δ 7.97 (dd, J=8.5, 5.9 Hz, 1H), 7.37 (dd, J=4.9, 3.0 Hz, 1H), 7.33 (dd, J=3.0, 1.4 Hz, 1H), 7.17-7.08 (m, 3H).

### 2-fluoro-6-(thiophen-3-yl)benzoic acid (4e)

¹H NMR (600 MHz, CDCl₃), δ (ppm): δ 7.52-7.45 (m, 1H), 7.42 (d, J=3.0 Hz, 2H), 7.34-7.27 (m, 2H), 7.25-7.20 (m, 1H), 7.15 (t, J=8.9 Hz, 1H); ¹³C NMR (125 MHz, CD₂Cl₂) δ (ppm): δ 170.04, 160.37, 158.71, 139.13, 139.11, 136.76, 136.74, 131.75, 131.69, 127.69, 126.20, 125.42, 125.39, 123.42, 120.19, 120.08, 114.60, 114.46. HRMS (EI+) cald. for C₁₁H₇O₂S₁F₁: 222.0151, found: 222.0149.

### 3-(benzo[b]thiophen-3-yl)benzoic acid (4f)

¹H NMR (600 MHz, CD₂Cl₂), δ (ppm): 8.06 (d, J=7.8 Hz, 1H), 7.92 (d, J=7.9 Hz, 1H), 7.66 (t, J=7.5 Hz, 1H), 7.53 (t, J=7.7 Hz, 1H), 7.47 (d, J=7.7 Hz, 1H), 7.43 (d, J=8.0 Hz, 1H), 7.39-7.30 (m, 3H).; ¹³C NMR (125 MHz, CD₂Cl₂) δ (ppm): 181.82, 139.57, 138.95, 136.77, 136.72, 134.66, 132.51, 131.91, 130.83, 127.96, 124.26, 124.22, 123.57, 122.64, 122.27. HRMS (EI+) cald. for C₁₅H₁₀O₂S₁: 254.0402, found: 254.0400.

### 8H-indeno[2,1-b]thiophen-8-one (5a)

Dissolve 3a (6 g, 29 mmol) in dry dichloromethane (40 ml). Add 1 ml of DMF and then slowly add oxalyl chloride (˜7 ml) at room temperature. Stir for 1 hour, or until no more bubbles generated. Remove DCM and excess of oxalyl chloride by vacuum distillation to obtain dark yellow oil. Add 5 ml dry DCM into the oil and transfer slowly to a DCM solution with AlCl₃ (9.7 g, 73 mmol). After complete transfer, heat the mixture to reflux for 1 hour. Cooled to room temperature, the mixture was poured into water with crushed ice and then extracted with DCM. Column chromatography with silica gel using DCM:hexane=3:7 gives compound 5a as bright yellow solid. 85%. ¹H NMR (600 MHz, CDCl₃), δ (ppm): 7.73 (d, J=4.7 Hz, 1H), 7.46 (d, J=7.3 Hz, 1H), 7.32 (t, J=7.5 Hz, 1H), 7.19-7.12 (m, 2H), 7.10 (d, J=4.7 Hz, 1H); ¹³C NMR (126 MHz, CDCl₃) δ (ppm): 185.62, 158.77, 139.72, 139.21, 137.91, 137.10, 133.70, 128.15, 124.07, 120.19, 119.60; HRMS (EI+) cald. For C₁₁H₆O₁S₁: 186.0139, found: 186.0140.

### 5-methyl-8H-indeno[2,1-b]thiophen-8-one (5b)

¹H NMR (600 MHz, CD₂Cl₂), δ (ppm): 7.75 (d, J=4.7 Hz, 1H), 7.32 (d, J=7.4 Hz, 1H), 7.13 (d, J=4.7 Hz, 1H), 7.04 (d, J=1.5 Hz, 1H), 6.97 (d, J=7.3 Hz, 1H), 2.36 (s, 5H); ¹³C NMR (125 MHz, CD₂Cl₂) δ (ppm): 185.20, 158.42, 144.91, 139.97, 138.72, 137.47, 135.32, 128.08, 123.76, 120.94, 120.17, 21.70; HRMS (EI+) cald. for C₁₂H₈O₂S₂: 200.0296, found: 200.0298.

### 5-(trifluoromethyl)-8H-indeno[2,1-b]thiophen-8-one (5c)

¹H NMR (600 MHz, CD₂Cl₂), δ (ppm): 7.87 (d, J=4.7 Hz, 1H), 7.56 (d, J=7.6 Hz, 1H), 7.50 (dd, J=7.7, 4.2 Hz, 1H), 7.46 (s, 1H), 7.22 (d, J=4.7 Hz, 1H).

### 5-fluoro-8H-indeno[2,1-b]thiophen-8-one (5d)

¹H NMR (600 MHz, CD₂Cl₂), δ (ppm): δ 7.80 (d, J=4.7 Hz, 1H), 7.45 (dd, J=8.1, 5.2 Hz, 1H), 7.16 (d, J=4.7 Hz, 1H), 6.95 (dd, J=8.3, 2.2 Hz, 1H), 6.84 (ddd, J=9.2, 8.0, 2.2 Hz, 1H). HRMS (EI+) cald. for C₁₁H₅O₁S₁F₁: 204.0045, found: 204.0041.

### 7-fluoro-8H-indeno[2,1-b]thiophen-8-one (5e)

¹H NMR (600 MHz, CD₂Cl₂), δ (ppm): δ 7.77 (d, J=4.7 Hz, 1H), 7.34 (ddd, J=8.6, 7.2, 5.0 Hz, 1H), 7.13 (d, J=4.7 Hz, 1H), 6.99 (d, J=7.2 Hz, 1H), 6.83 (t, J=8.9 Hz, 1H); ¹³C NMR (125 MHz, CD₂Cl₂) δ (ppm): 181.53, 159.34, 157.61, 157.42, 157.39, 141.49, 141.47, 139.23, 136.37, 136.31, 122.44, 122.36, 120.27, 117.31, 117.17, 116.01, 115.99. HRMS (EI+) cald. for C₁₁H₅O₁S₁F₁: 204.0045, found: 204.0037.

### 6H-benzo[b]indeno[1,2-d]thiophen-6-one (5f)

¹H NMR (600 MHz, CD₂Cl₂), δ (ppm): 8.03 (d, J=7.7 Hz, 1H), 7.87 (d, J=8.0 Hz, 1H), 7.53-7.41 (m, 4H), 7.39 (t, J=7.5 Hz, 1H), 7.19 (t, J=7.4 Hz, 1H); ¹³C NMR (125 MHz, CD₂Cl₂) δ (ppm): 186.84, 152.79, 148.21, 140.17, 137.09, 136.94, 133.78, 131.98, 128.15, 127.57, 125.88, 124.52, 123.99, 123.59, 119.75. HRMS (EI+) cald. for C₁₅H₈O₁S₁: 236.0296, found: 236.0299.

### (E)-8,8′-biindeno[2,1-b]thiophenylidene (1a)

Dissolved ketone 4a (1.55 g, 8.3 mmol) in 40 ml dry toluene and then added Lawesson's reagent (4 g, 9.9 mmol). The mixture was heated at 90° C. overnight and brick red solution generated. Cooled down to room temperature, the solution was run through a short pad of basic alumina oxide using toluene to wash until colorless filtrate was observed. Concentrated and purified by column chromatography (10% CH₂Cl₂ in hexane) affords the isomers as dark red solid. 90%. ¹H-NMR (400 MHz, CDCl₃), δ (ppm): 8.50 (d, J=7.7 Hz, 2H), 8.33 (d, J=7.7 Hz, 2H), 7.49 (d, J=4.9 Hz, 2H), 7.46 (m, 4H), 7.40 (d, J=5.0 Hz, 2H), 7.32 (t, J=7.4 Hz, 2H), 7.28 (d, J=4.9 Hz, 2H), 7.26 (t, J=4.9 Hz, 2H), 7.24 (t, J=4.9 Hz, 2H) 7.22 (d, J=5.0 Hz, 2H), 7.12 (t, J=7.7 Hz, 2H); ¹³C NMR (125 MHz, CDCl₃) δ (ppm): 149.27, 149.22, 141.50, 140.50, 140.02, 139.49, 138.42, 137.76, 133.50, 133.24, 130.75, 130.69, 129.14, 128.76, 127.37, 125.44, 125.39, 125.00, 119.61, 119.58, 119.02, 118.91; HRMS (EI+) cald. for C₂₂H₁₂S₂: 340.0380, found: 340.0376. Trans isomer of 1 was obtained by recrystallization from CH₂Cl₂ and hexane to afford red needle crystals. 1H NMR (600 MHz, CD₂Cl₂) δ (ppm): 8.50 (d, J=7.7 Hz, 2H), 7.47 (d, J=7.4 Hz, 2H), 7.40 (d, J=5.0 Hz, 2H), 7.32 (t, J=7.5 Hz, 2H), 7.24 (t, J=7.6 Hz, 2H), 7.22 (d, J=4.9 Hz, 2H).

### 5,5′-dimethyl-8,8′-biindeno[2,1-b]thiophenylidene (1b)

¹H NMR (600 MHz, CD₂Cl₂) δ (ppm): 8.36 (d, J=7.8 Hz, 1H), 8.19 (d, J=7.9 Hz, 1H), 7.46 (d, J=4.9 Hz, 1H), 7.37 (d, J=5.0 Hz), 7.30 (s), 7.28 (s), 7.25 (d, J=4.9 Hz), 7.19 (d, J=5.0 Hz), 7.05 (d, J=8.0 Hz), 6.94 (d, J=8.3 Hz), 2.43 (s), 2.41 (s); ¹³C NMR (126 MHz, CD₂Cl₂) δ (ppm): 149.01, 148.87, 140.05, 139.66, 139.59, 139.15, 138.66, 138.45, 137.85, 137.73, 132.73, 132.47, 130.52, 130.43, 127.03, 125.87, 125.61, 125.12, 120.56, 120.47, 118.93, 118.81, 53.83, 53.62, 53.40, 53.18, 52.97, 21.46, 21.35; HRMS (EI+) cald. for C₂₄H₁₆S₂: 368.0693, found: 368.0691.

### 5,5′-bis(trifluoromethyl)-8,8′-biindeno[2,1-b]thiophenylidene (1c)

¹H NMR (600 MHz, CDCl₃), δ (ppm): 8.57 (d, J=8.0 Hz), 8.30 (d, J=8.1 Hz), 7.64 (s), 7.52 (d, J=4.9 Hz, cis), 7.49 (dd, J=8.1, 1.7 Hz, cis), 7.43 (d, J=5.0 Hz, trans), 7.37 (d, J=8.4 Hz), 7.28 (d, J=4.9 Hz), 7.21 (d, J=5.0 Hz); HRMS (EI+) cald. for C₂₄H₁₀F₆S₂: 476.0128, found: 476.0125.

### 5,5′-difluoro-8,8′-biindeno[2,1-b]thiophenylidene (1d)

¹H NMR (600 MHz, CDCl₃), δ (ppm): 8.44 (dd, J=8.5, 5.0 Hz), 8.21 (dd, J=8.6, 5.1 Hz), 7.52 (d, J=4.9 Hz), 7.43 (d, J=4.9 Hz), 7.27 (d, J=4.9 Hz), 7.24-7.12 (m), 6.93 (td, J=8.8, 2.5 Hz), 6.87-6.79 (m). HRMS (EI+) cald. for C₂₂H₁₀F₂S₂: 376.0192, found: 376.0185.

### 7,7′-difluoro-8,8′-biindeno[2,1-b]thiophenylidene (1e)

1H NMR (600 MHz, CD₂Cl₂), δ (ppm): δ 7.49 (d, J=4.9 Hz, 1H), 7.34 (dtd, J=8.0, 4.2, 2.1 Hz, 1H), 7.31-7.28 (m, 2H), 6.91-6.84 (m, 1H).

### 6,6′-bibenzo[b]indeno[1,2-d]thiophenylidene (1f)

¹H NMR (600 MHz, CD₂Cl₂), δ (ppm): 1H NMR (500 MHz, Methylene Chloride-d2) δ 8.63 (d, J=7.7 Hz, 2H), 8.13 (d, J=8.0 Hz, 2H), 7.82 (dd, J=12.5, 7.7 Hz, 4H), 7.50 (t, J=7.5 Hz, 2H), 7.42 (dt, J=14.7, 7.5 Hz, 4H), 7.32 (t, J=7.6 Hz, 2H). HRMS (EI+) cald. for C₃₀H₁₆S₂: 440.0693, found: 440.0692.

### (E)-2,2′-dibromo-8,8′-biindeno[2,1-b]thiophenylidene (tBTP-Br)

tBTP (297 milligrams (mg), 0.87 mmol) was dissolved in dry dichloromethane and cooled with ice/water. Then added NBS (326 mg, 1.83 mmol) in dark and the solution was covered with aluminum foil and stirred overnight. After reaction, poured the solution in MeOH and vigorously stirred for 5 minutes. Collected the dark red precipitate and washed with H₂O and MeOH. The crude product was used without further purification. 96%. ¹H-NMR (600 MHz, CDCl₃), δ (ppm): 8.31 (d, J=7.6 Hz, 2H), 7.37 (d, J=7.3 Hz, 2H), 7.29 (t, J=7.5 Hz, 2H), 7.24 (t, 2H), 7.21 (s, 2H); ¹³C-NMR (100 MHz, CDCl₃) δ (ppm): 148.13, 140.16, 138.90, 137.28, 133.08, 129.34, 125.96, 124.99, 122.30, 119.76, 117.90; HRMS (EI+) cald. for C₂₂H₁₀Br₂S₂: 495.8591, found: 495.8593.

### (E)-2,2′-bis(trimethylstannyl)-8,8′-biindeno[2,1-b]thiophenylidene (tBTP-Sn)

tBTP-Br (48.29 mg, 0.1 mmol) was dissolved in dry THF and cooled at −78° C. Under Argon (Ar), n-butyl lithium (0.1 ml, 2.5 M in hexane) was slowly added. After stirring at the same temperature for 40 min, and SnMe3Cl (0.3 ml, 1 M in THF) was added at once. After addition of the SnMe3Cl, the mixture was stirred for 30 min and then warmed to room temperature. The mixture was poured into H₂O and extracted with diethyl ether (50 ml). The ether solution was then dried with MgSO₄ and concentrated. tBTP-Sn was obtained from recrystallization in CH₂Cl₂ and MeOH as dark brown crystals in 86% yield. ¹H-NMR (600 MHz, CD₂Cl₂), δ (ppm): 8.54 (d, J=7.6 Hz, 2H), 7.46 (d, J=7.3 Hz, 2H), 7.30 (t, J=7.3 Hz, 2H), 7.29 (s, 2H), 7.24 (t, J=7.6 Hz, 2H), 0.48 (s, 18H); ¹³C-NMR (100 MHz, CD₂Cl₂) δ (ppm): 150.98, 147.16, 146.12, 142.70, 137.95, 132.88, 129.35, 126.95, 126.00, 125.64, 119.93, −8.07; LRMS (FD+) cald. for C₂₈H₂₈S₂Sn₂: 665.97, found: 665.97.

### Poly((E)-3-(5-([8,8′-biindeno[2,1-b]thiophenylidene]-2-yl)thiophen-2-yl)-2,5-bis(2-octyldodecyl)-6-(thiophen-2-yl)pyrrolo[3,4-c]pyrrole-1,4(2H,5H)-dione) (PtBTPDPP)

tBTP-Sn (28 mg, 0.042 mmol), 3,6-bis(5-bromothiophen-2-yl)-2,5-diicosylpyrrolo[3,4-c]pyrrole-1,4(2H,5H)-dione (43 mg, 0.042 mmol), Pd(PPh₃)₄ (2.4 mg, 5 mol %), and tri(o-tolyl)phosphine (2.6 mg, 20 mole percent (mol %)) were added to 2 mL of anhydrous xylenes. The resulting reaction mixture was heated at 80° C. for 2 min, 130° C. for 2 min, 170° C. for 2 min and then 200° C. for 40 min in a microwave reactor (Biotage Initiator Eight). The reaction mixture was then cooled to room temperature, and the polymer was precipitated into methanol. The precipitated polymer was then filtered and purified by Soxhlet extraction using acetone and hexane. The resulting polymer was then retrieved with by chloroform. Finally, the chloroform solution was concentrated and poured into methanol to receive the target polymer. Yield: 82%. Mₙ=61.9 K, M_{w}=130.5 K and PDI=2.10.

Synthesis of PtBTP2T follows the same procedure as mentioned above. Gel permeation Chromatography (GPC) shows Mₙ=16.0 K, M_{w}=28.0 K and PDI=1.75.

### Poly((E)-2-(4,8-bis(icosyloxy)benzo[1,2-b:4,5-b′]dithiophen-2-yl)-8,8′-biindeno[2,1-b]thiophenylidene) (PtBTPBDT)

tBTP-Br (80 mg, 0.161 mmol), (4,8-bis(icosyloxy)benzo[1,2-b:4,5-b′]dithiophene-2,6-diyl)bis(trimethylstannane) (178.1 mg, 0.161 mmol), Pd₂dba₃ (7.35 mg, 5 mol %), and tri(o-tolyl)phosphine (9.77 mg, 20 mol %) were added to 2 mL of anhydrous chlorobenzene. The resulting reaction mixture was heated at 145° C. for 24 hours. The workup procedure is the same as described for PtBTPDPP. Yield: 81%. Mₙ=70.1 K, M_{w}=133 K, and PDI=1.90.

Synthesis of PcBTPBDT, P4FBTPBDT, P4FBTPDTS and PtBTPIDT followed the same procedure as above.

Advantages and Improvements

As discussed above, we have synthesized and characterized a new class of building blocks for low bandgap conjugated polymers, and demonstrated their potential for use in organic solar cell and organic thin film transistor devices. BTP derivatives can be easily synthesized and converted to brominated and stannylated derivatives for various polymerization reactions. The synthetic strategy is modular and very flexible, enabling preparation of a wide range of BTP type materials which can be structurally and electrochemically fine-tuned to accommodate different needs in organic electronics applications. The BTP compounds also shows promising photophysical and electron accepting properties, and therefore have the potential to serve as an n-type material for high V_{oc} organic solar cells and organic thin film transistors. BTP-based copolymers exhibit wide absorption, spanning from the visible (VIS) to the near infrared (NIR) region, and have a bandgap as low as 1.21 eV, which make them suitable in both single junction and tandem solar cells. Current results from tBTP-based polymer devices show photovoltaic power conversion efficiency up to 4%, and electron and/or hole mobility up to 0.09 cm²/Vs BTP is an alternative to fullerene type materials as an n-type material in organic solar cells. BTP also provides numerous options to be electronically functionalized, to accommodate different needs in organic electronic applications.

These results create another possibility for the community currently looking for high performance organic transistors and solar cells (e.g., showing that BTP-based copolymers represent a new class of low bandgap conjugated polymers desired in organic tandem solar cells).

In addition, one or more embodiments of the invention disclose the synthesis of BTP is simple and with good yields. Moreover, the same synthetic strategy can be used for structurally similar materials, but with different substituted aromatic and heteroaromatic compounds. For example, one or more suitable monomers can be found to copolymerize with the BTP-based monomer (e.g., structurally similar monomers (e.g. pyridine based) can be found to form high efficiency solar cells and higher performance transistor devices).

### REFERENCES

The following references are incorporated by reference herein.
[1] Allard et al., Angew. Chem. Int. Ed. 47, 4070-4098 (2008).
[2] Diao et al., Nat. Mater. 2013, 12, (7), 7.
[3] Minemawari et al. Nature 2011, 475, (7356).
[4] Li et al., Sci. Rep. 2012, 2, 9).
[5] Guo et al., Adv. Mater. 2010, 22, (40), 4427-4447.
[6] Arias et al., Chem. Rev. 2010, 110, (1), 3-24.
[7] Sirringhaus, H. Adv. Mater. 2005, 17, (20), 2411-2425).
[8] McCulloch et al., Nat. Mater. 2006, 5, (4); and Yan et al., Nature 2009, 457, (7230).
[9] C. W. Tang, Appl. Phys. Lett. 1986, 48, 183.
[10] C. Silva, Nat. Mater. 2013, 12, 5-6.
[11] B. C. Thompson, J. M. J. Frechet, Angew. Chem.-Int. Ed. 2008, 47, 58-77.
[12] M. Kaltenbrunner, M. S. White, E. D. Glowacki, T. Sekitani, T. Someya, N. S. Sariciftci, S. Bauer, Nat. Commun. 2012, 3, 770.
[13] C. J. Brabec, S. Gowrisanker, J. J. M. Halls, D. Laird, S. Jia, S. P. Williams, Adv. Mater. 2010, 22, 3839-3856.
[14] K. H. Hendriks, G. H. L. Heintges, V. S. Gevaerts, M. M. Wienk, R. A. J. Janssen, Angew. Chem.-Int. Ed. 2013, 52, 8341-8344.
[15] X. Guo, N. Zhou, S. J. Lou, J. Smith, D. B. Tice, J. W. Hennek, R. Ponce Ortiz, J. T. Lopez Navarrete, S. Li, J. Strzalka, et al., Nat. Photonics 2013, 7, 825-833.
[16] H. Zhou, L. Yang, W. You, Macromolecules 2012, 45, 607-632.
[17] Z. He, C. Zhong, S. Su, M. Xu, H. Wu, Y. Cao, Nat. Photonics 2012, 6, 591-595.
[18] N. Li, D. Baran, K. Forberich, F. Machui, T. Ameri, M. Turbiez, M. Carrasco-Orozco, M. Drees, A. Facchetti, F. C. Krebs, et al., Energy Environ. Sci. 2013, 6, 3407-3413.
[19] J. Y. Kim, K. Lee, N. E. Coates, D. Moses, T.-Q. Nguyen, M. Dante, A. J. Heeger, Science 2007, 317, 222-225.
[20] J. You, L. Dou, Z. Hong, G. Li, Y. Yang, Prog. Polym. Sci. n.d., DOI 10.1016/j.progpolymsci.2013.04.005.
[21] V. S. Gevaerts, A. Furlan, M. M. Wienk, M. Turbiez, R. A. J. Janssen, Adv. Mater. 2012, 24, 2130-2134.
[22] J. You, L. Dou, K. Yoshimura, T. Kato, K. Ohya, T. Moriarty, K. Emery, C.-C. Chen, J. Gao, G. Li, et al., Nat. Commun. 2013, 4, DOI 10.1038/ncomms2411.
[23] F. G. Brunetti, X. Gong, M. Tong, A. J. Heeger, F. Wudl, Angew. Chem. Int. Ed. 2010, 49, 532-536.
[24] X. Gong, M. Tong, F. G. Brunetti, J. Seo, Y. Sun, D. Moses, F. Wudl, A. J. Heeger, Adv. Mater. 2011, 23, 2272-2277.
[25] Y. Cohen, J. Klein, M. Rabinovitz, J. Chem. Soc. Chem. Commun. 1986, 1071-1073.
[26] M. Otero, E. Roman, E. Samuel, D. Gourier, J. Electroanal. Chem. 1992, 325, 143-152.
[27] Chien-Yang Chiu, Hengbin Wang, Fulvio G. Brunetti, Fred Wudl, and Craig J. Hawker, Angew. Chem. Int. Ed., 2014, 53, 3996-4000, and supporting information.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A composition of matter, comprising a polymer having the following structural formula: 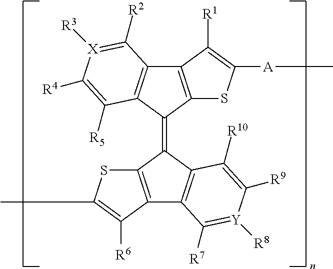
wherein:
X and Y are at least one unit chosen from Carbon (C) and Nitrogen (N);
A is a monomer; and
R¹-R¹⁰ are at least one member chosen from hydrogen, a halogen, an alkyl, a cyclic alkyl, a heterocyclic, an alkyloxy, an alkylthio, an alkenyl, an alkynyl, an aryl, an aryloxy, an arylthio, a heteroaryl, a fluoroaryl, an amido, an amino, an acyl, a carboxyl, a cyano, an epoxy, a carboxylate, a nitro, a carbonyl, a sulfonyl, a sulfinyl, a cyano, a hydroxyl, a thiol, a silyl, a siloxy, a silyloxy, an azo, a boryl, a phosphoryl, and a phosphinyl, and R² and R¹⁰ can equal to nothing when X or Y is nitrogen.

2. The composition of matter of claim 1, wherein the polymer comprises repeating units chosen from PtBTP2T, PtBTPDPP, PtBTPBDT, P4FBTPBDT, P4FBTPDTS, and PtBTPIDT.

3. The polymer of claim 1, fabricated using a process comprising:
Suzuki-Miyaura coupling methyl 2-bromobenzoate to form compound x;
hydrolyzing the compound x to form compound y;
performing a Friedel-Crafts reaction on compound y to afford a ketone;
synthesizing BTP from the ketone by Lawesson's reagent;
selecting one or more isomers of the BTP; and
brominating and stannylating the isomers and performing polymerization reactions on the brominated and stannylated isomers to form the polymer.

4. The polymer of claim 1, where the polymer has the following structure: 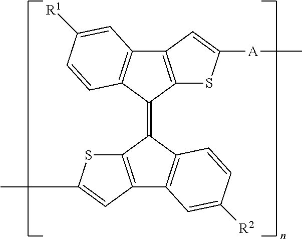
wherein:
R¹-R² are at least one member chosen from the hydrogen, the halogen, the alkyl, the cyclic alkyl, the heterocyclic, the alkyloxy, the alkylthio, the alkenyl, the alkynyl, the aryl, the aryloxy, the arylthio, the heteroaryl, the fluoroaryl, the amido, the amino, the acyl, the carboxyl, the cyano, the epoxy, the carboxylate, the nitro, the carbonyl, the sulfonyl, the sulfinyl, the cyano, the hydroxyl, the thiol, the silyl, the siloxy, the silyloxy, the azo, the boryl, the phosphoryl, and the phosphinyl.

5. The polymer of claim 1, wherein:
the polymer comprises a plurality of (E)-8,8′-biindeno[2,1-b]thiophenylidene (BTP) units,
each BTP unit has a nonplanar twisted structure having a splay angle between proximal aromatic rings of about 20-30 degrees.

6. The polymer of claim 5, wherein the splay angle is such that the BTP is soluble in at least one solvent chosen from Tetrahydrofuran (THF), dichloromethane, ethyl acetate, and hexane.

7. The polymer of claim 1, wherein the polymer's backbone is sufficiently rigid such that absorption profiles of the polymers in solution and film state are essentially identical.

8. The polymer of claim 1, wherein the polymer is functionalized to have an optical bandgap in a range of 1.21-2.10 electron volts (eV).

9. The polymer of claim 1, wherein the polymer is functionalized or copolymerized to have a peak absorption at a wavelength between 600 nanometers (nm) and 900 nm.

10. The polymer of claim 1, wherein the polymer is functionalized for solution casting on a device substrate, wherein the device is an organic light emitting device, organic light emitting diode, organic transistor, or organic photovoltaic device.

11. The polymer of claim 1, comprising a copolymer with the monomer chosen from diketopyrrolopyrrole (DPP), dithienylsilole (DTS), bisthiophene (2T), indacenodithiophene (IDT), and benzodithiophene (BDT).

12. A photovoltaic device comprising the polymer of claim 1, wherein the polymer comprises:
an active region, comprising an acceptor and a donor, the active region producing electrical power in response to incident electromagnetic radiation.

13. The photovoltaic device of claim 12, further comprising:
a photovoltaic cell structure on a substrate, the photovoltaic cell structure including the active region comprising the acceptor and donor combined in a film on or above the substrate, the film having a structure, crystallinity, morphology, and thickness, donor/acceptor ratio, and amount of the polymer, wherein:
measured at 1 sun (AM 1.5G), the photovoltaic cell structure has:
an open circuit voltage V_{oc} of at least 0.7 V;
a short circuit voltage J_{sc} of at least 8 mA/cm²;
a fill factor ff of at least 0.65; and
an efficiency η of at least 4.1%.

14. The photovoltaic device of claim 12, wherein the polymer is functionalized to have an optical bandgap of at most 1.5 electron volts (eV).

15. An organic field effect transistor (FET) comprising the polymer of claim 1, wherein:
compound B has the structural formula: 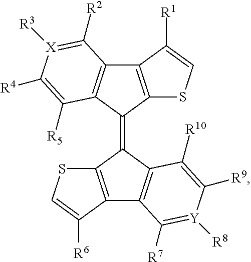
the polymer comprises a donor and an acceptor,
A comprises the donor and the compound B comprises acceptor, or A comprises the acceptor and the compound B comprises the donor, and
the FET has an electron and/or hole mobility of at least 0.09 cm²/Vs.

16. A film comprising the polymer of claim 1, comprising:
an amount of the compound B having the structural formula: 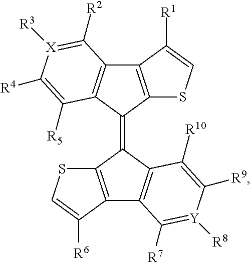
the amount adjusted relative to an amount of cis-isomer of B in the film, such that the film's carrier mobility is increased as compared to a carrier mobility of a control film where an amount of B is not adjusted relative to the amount of the cis-isomer.

17. An organic field effect transistor (FET) comprising the film of claim 16, wherein the film comprises a conductive channel, the FET further comprising:
a substrate, wherein the film is on or above the substrate;
a source contact and a drain contact electrically contacting the film, for passing a current through the conductive channel between the source contact and the drain contact; and
a gate for controlling the current's flow when a voltage bias is applied across a dielectric layer between the conductive channel and the gate; wherein:
the polymer comprises a donor and an acceptor,
A comprises the donor and B comprises acceptor, or A comprises the acceptor and B comprises the donor,
the film is processed from a composition comprising the polymer dissolved in a solvent,
the substrate, the source contact, the drain contact, the gate, the dielectric layer, a donor/acceptor ratio, the film's thickness, the composition, and the amount of B are effective to achieve an electron and/or hole mobility of at least 0.09 cm²/Vs.

18. A film comprising one or more polymer chains comprising the polymer of claim 1, the polymer comprising an isomerically tuned linear polymer, the isomerically tuned linear polymer having an amount of compound comprising a trans isomer structure adjusted relative to an amount of cis-isomer of the compound in the film, such that the film's carrier mobility is isomerically tuned.

19. A film, comprising:
one or more polymer chains comprising an isomerically tuned linear polymer, the isomerically tuned linear polymer having an amount of compound comprising a trans isomer structure adjusted relative to an amount of cis-isomer of the compound in the film, such that the film's carrier mobility is isomerically tuned.

20. The film of claim 19, wherein the isomerically tuned linear polymer has the following structural formula: 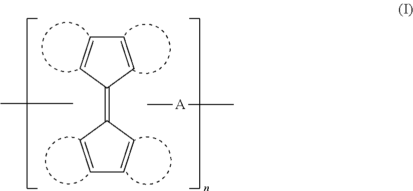
where 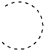
represents mono-cyclic or polycyclic aromatic rings fused to the fulvalene core, with or without substituents, wherein two of the rings comprise thiophene rings having Sulfur atoms positioned to form a trans isomer structure; and
A is a monomer.

21. A device comprising a mixture of a polymer (I) and one or more fullerene derivatives, wherein the polymer (I) has the following structural formula: 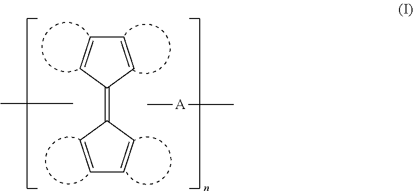
where 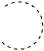
represents mono-cyclic or polycyclic aromatic rings fused to the fulvalene core, with or without substituents, wherein the four rings are the same or different; and
A is a monomer.

22. The device of claim 21, wherein the polymer comprises repeating units chosen from PtBTP2T, PtBTPDPP, PtBTPBDT, P4FBTPBDT, P4FBTPDTS, and PtBTPIDT.
